(19) United States
(12) Patent Application Publication
(10) Pub. No.: US 2013/0081938 A1
(43) Pub. Date: Apr. 4, 2013

(54) MAGNETRON SPUTTERING APPARATUS AND METHOD

(71) Applicants: Shigeru MIZUNO, Yamanashi (JP); Hiroyuki TOSHIMA, Yamanashi (JP); Atsushi GOMI, Yamanashi (JP); Tetsuya MIYASHITA, Yamanashi (JP); Tatsuo HATANO, Yamanashi (JP); Yasushi MIZUSAWA, Yamanashi (JP)

(72) Inventors: Shigeru MIZUNO, Yamanashi (JP); Hiroyuki TOSHIMA, Yamanashi (JP); Atsushi GOMI, Yamanashi (JP); Tetsuya MIYASHITA, Yamanashi (JP); Tatsuo HATANO, Yamanashi (JP); Yasushi MIZUSAWA, Yamanashi (JP)

(21) Appl. No.: 13/630,629

(22) Filed: Sep. 28, 2012

(30) Foreign Application Priority Data
Sep. 30, 2011 (JP) 2011-216104
Aug. 2, 2012 (JP) 2012-172387

(51) Int. Cl. C23C 14/35

(52) U.S. Cl. 204/192.12; 204/298.16; 204/298.12

(57) ABSTRACT

A magnetron sputtering apparatus in which a target is disposed to face a substrate includes a magnet array body including a magnet group arranged on a base body, and a rotating mechanism for rotating the magnet array body around an axis perpendicular to the substrate. In the magnet array body, N poles and S poles constituting the magnet group are arranged to be spaced from each other along a surface facing the target such that a plasma is generated based on a drift of electrons by a cusp magnetic field. Magnets located on the outermost periphery of the magnet group are arranged in a line to prevent the electrons from being released from constraint of the cusp magnetic field and jumping out of the cusp magnetic field. A distance between the target and the substrate during sputtering is equal to or less than 30 mm.

### CROSS-REFERENCE TO RELATED APPLICATION

This application claims priority to Japanese Patent Application Nos. 2011-216104 and 2012-172387 filed on Sep. 30, 2011 and Aug. 2, 2012, respectively, the entire contents of which are incorporated herein by reference.

### FIELD OF THE INVENTION

The present invention relates to a magnetron sputtering apparatus and method.

### BACKGROUND OF THE INVENTION

A magnetron sputtering apparatus used in a manufacturing process of semiconductor devices, for example, as shown in FIG. 33, is configured such that a target 13 made of a film forming material is disposed to face a substrate 12 in a vacuum chamber 11 set to a low pressure atmosphere, a magnet body 14 is provided at the top side of the target 13, and if the target 13 is a conductor such as metal, a magnetic field is formed in the vicinity of the lower surface of the target 13 in a state where a negative DC voltage is applied. Further, there is provided an anti-adhesion shield (not shown) to prevent the adhesion of particles to the inner wall of the vacuum chamber 11.

The magnet body 14, as shown in FIG. 34, is generally configured such that, for example, a circular magnet 16 having a polarity different from that of an annular magnet 15 is disposed on the inside of the magnet 15. Further, FIG. 34 is a plan view of the magnet body 14 when seen from the target 13. In this example, the polarity of the outer magnet 15 facing the target 13 is set to an S pole, and the polarity of the inner magnet 16 facing the target 13 is set to an N pole. Thus, in the vicinity of the lower surface of the target 13, a horizontal magnetic field is formed by a cusp magnetic field based on the outer magnet 15 and a cusp magnetic field based on the inner magnet 16.

When a negative DC voltage is applied to the target 13 from a DC power supply unit 19 while introducing an inert gas such as Ar gas in the vacuum chamber 11, the Ar gas is ionized by the electric field to generate electrons. The electrons drift by the horizontal magnetic field and electric field, thereby forming a high density plasma. Then, Ar ions in the plasma sputter the target 13 to release metal particles from the target 13, and deposition is performed on the substrate 12 by the released metal particles.

By such a mechanism, as shown in FIG. 35, on the lower surface of the target 13, annular erosion 17 is formed according to the array of magnets directly under a middle portion of the inner magnet 16 and the outer magnet 15. In this case, the magnet body 14 is rotated to form the erosion 17 on the entire surface of the target 13. However, in the above-described array of magnets, it is difficult to uniformly form the erosion 17 in the radial direction of the target 13.

On the other hand, deposition rate distribution in the surface of the substrate depends on the intensity of the erosion 17 (the magnitude of the sputtering speed) in the surface of the target 13. Therefore, if the degree of non-uniformity of the erosion 17 is large as described above, in case of reducing a distance between the target 13 and the substrate 12 as shown by a dotted line in FIG. 35, the shape of the erosion is reflected as it is, and the uniformity of the deposition rate in the surface of the substrate deteriorates. For this reason, conventionally, a sputtering process is performed in a state that the distance between the target 13 and the substrate is set to be large, e.g., about 50 mm to 100 mm.

In this case, the particles emitted from the target 13 by sputtering scatter to the outside, so that if the substrate 12 is separated from the target 13, the amount of sputtered particles adhering to the anti-adhesion shield becomes larger, and the deposition rate of an outer peripheral portion of the substrate is lowered. Accordingly, the uniformity of the deposition rate in the surface of the substrate is generally ensured by making the erosion of the outer periphery deep, i.e., increasing the sputtering rate of the outer periphery. However, in this configuration, since the amount of sputtered particles adhering to the anti-adhesion shield becomes larger as described above, the deposition efficiency is very low as about 10% and a high deposition rate cannot be obtained. Thus, in the conventional magnetron sputtering apparatus, it is difficult to make the uniformity of the deposition rate compatible with the deposition efficiency.

Also, it is necessary to replace the target 13 just before the erosion 17 reaches the backside. However, as previously described, if the in-plane uniformity of the erosion 17 is low and there locally exists a site where the progress of erosion is rapid, since the time of replacing the target 13 is determined in accordance with this site, the utilization efficiency of the target 13 is as low as about 40%. In order to reduce the manufacturing cost and improve productivity, it is also required to increase the utilization efficiency of the target 13.

In recent years, a tungsten (W) film has been attracting attention as a wiring material of memory devices, and it has been requested to form a film at a deposition rate of about 300 nm/min. In the above configuration, it is possible to ensure the deposition rate by increasing the applied power to, e.g., about 15 kWh; however, the mechanism is complex, the operation rate is low, and the manufacturing cost becomes high.

Here, in Japanese Patent Application Publication No. 2004-162138, there has been proposed a configuration in which a plurality of magnets having an equal distance between any two magnets and having alternating polarities are arranged in a plane to face the target to generate a point-cusp magnetic field below the target. If the magnets generating the point-cusp magnetic field are referred to as point-shaped magnets, in the configuration in which the point-shaped magnets are arranged, the electrons are accelerated by E×B due to the electric field E in the vicinity of the target and the horizontal magnetic field B of the point-shaped magnets, and drift to generate a plasma.

However, in the outer periphery of the magnet array, since there exists an open end where a vector direction of E×B is toward the outside of the target by the arrangement of N and S, electrons jump out of the outer periphery of the target, and electron loss becomes large. Here, in order to form the erosion on the entire surface of the target, it is necessary to arrange the point-shaped magnets such that the horizontal magnetic field covers the outer periphery of the target. In this case, since the open end is located near the outer periphery of the target, if electrons jump out of the outer periphery of the target, sparse and dense of the electron density may occur in the circumferential direction at the outer periphery, or the electron density may decrease in the radial direction of the target, which results in the non-uniformity of the electron density. For this reason, the in-plane uniformity of plasma density is lowered and the electron density differs from place to place immediately below the target. Further, since the magnetic flux near the open end diverges, the flux balance is lost, and the non-uniformity of the electron density increases.

In the array of only the point-shaped magnets, although the horizontal magnetic field generated between the magnets expands two-dimensionally by the magnet array, sufficient plasma density cannot be obtained, and it is difficult to ensure the in-plane uniformity of high plasma density. In addition, the in-plane uniformity of erosion decreases depending on the density of the periodic horizontal magnetic field due to the array of the point-shaped magnets, but is further lowered according to the plasma density. Consequently, the utilization efficiency of the target is reduced. In this case, it is also considered to eliminate the problem due to the open end by making a forming region of a magnet group larger than the target. However, if there is a strong magnetic field between the target and the shield member, it may cause abnormal discharge. Accordingly, it is not preferable to make the forming region of the magnet group larger than the target.

Further, in Japanese Patent Application Publication No. 2000-309867, there has been described a technology in which a plurality of magnets, each having a central axis parallel to the surface of the target, are arranged such that their central axes are substantially parallel to each other, and are formed such that N and S poles face each other in a direction substantially perpendicular to the central axis. Further, in Japanese Patent Application Publication No. H9-118979, there has been described a technology to improve the coverage by reducing a distance between the target and the wafer.

However, the above-cited references have not been focused on narrowing the distance between the target and the substrate and improving the efficiency of deposition while ensuring the in-plane uniformity of the deposition rate. Even if the configurations of the above-cited references are applied, the problem to be solved by the present invention cannot be solved.

Further, tungsten (W) has been considered to be deposited by the magnetron sputtering method as described above, but has been attracting attention as reliable high melting point metal in which an increase in resistance does not occur even in fine wiring. Thus, when using the magnetron sputtering method, it is requested that the deposition rate is high, and the deposited film has a low resistance.

A bulk resistivity of tungsten (W) is about 5.3 μΩ·cm at room temperature. In a recent multilayer wiring circuit, high-speed deposition of, e.g., 300 nm/min or more and resistivity of 10 μΩ·cm or less have been requested. However, in the conventional technology, in addition to the problem that the deposition efficiency and the utilization efficiency of the target are low as described above, there is a problem such that there is a trade-off relationship between forming the tungsten (W) film to have a low resistance and obtaining a high deposition rate. In case of increasing the deposition rate, generally, the voltage applied from the DC power supply unit 19 is increased, but the resistivity of the sputtered film increases as a result. As an example, the resistivity of the film that can be obtained at a deposition rate of about 50 nm/min is about 10 μΩ·cm, but the resistivity at a high deposition rate of about 300 nm/min is about 11 μΩ·cm to 20 μΩ·cm or more, which is about 2 to 3 times the bulk value.

The causes of the increase in wiring resistance are electron scattering at the grain boundary of crystal grains in the film, electron scattering by lattice defects in the film, electron scattering by impurities (including Ar in case of sputtering), and electron scattering at the surface and the interface. Accordingly, in order to lower the resistance of the sputtered film, it is important to align the crystal orientation and crystal grain size of the film, and reduce the defects and impurities in the film. In order to effectively perform these, it is required to make it easier to perform the rearrangement of particles by the vigorous surface diffusion of W particles during the sputter deposition.

According to a document (J. A. Thornton; Ann. Rev. Mater. Sci. 7 (1977) p. 239), in order to perform the rearrangement of particles in sputter deposition, first, it is important to increase the substrate temperature. Since the W film is made of high melting point metal, a high temperature equal to or greater than 850° C. is required to cause the surface diffusion. It is difficult to apply this technique to a general sputtering technology. Further, although it can be recrystallized to have a low resistance by annealing after deposition, since a higher temperature of 1000° C. is necessary, it is not allowed in the semiconductor manufacturing process.

Further, it has been known that a low pressure condition in which the energy of the sputtered atoms can be used is preferable to cause the surface diffusion. That is, it has been known that a target voltage is generally 200 V to 800 V, and the energy of the sputter gas atoms, e.g., argon (Ar) atoms, accelerated by this voltage is 10 eV to 20 eV. This is because if there is no collision in a space due to a low pressure, the sputtered atoms reach the surface of the film on the substrate by this energy to contribute to the energy diffusion on the surface of the film. It has been known that 10 mTorr or less is preferable if a distance between the target and the substrate is 30 mm to 100 mm. However, in combination of W and Ar, under low pressure, Ar ions make an elastic collision with the W film that is the target to be converted into neutral Ar atoms which rebound, and rush into the W film deposited on the substrate to cause damage. Since rushing of the Ar atoms to the W film is elastic collision, the energy of the rebounding Ar atoms is large as the atomic weight of the target material elements is large. If the target is the W film, the energy of the rebounding Ar atoms is 100 eV to 200 eV. A threshold voltage of the sputtered W film is about 33 eV, and the energy of the rebounding Ar atoms is large compared with this value. It is obvious that it could be a cause generating a large amount of defects in the film. Also, the amount of Ar in the film increases, which becomes a cause of the increase in resistance along with the defects. When increasing the voltage applied from the DC power supply unit to increase the deposition rate under these circumstances, the target voltage increases, and the energy of Ar atoms rebounding from the target surface also increases. Accordingly, the defects of the film further increase, and the resistivity of the film increases.

In order to solve the problem of the rebounding Ar atoms, a method of using a low pressure Kr gas has been disclosed in U.S. Patent Application Publication No. 2004/0214417. Since Kr is larger than Ar in both the mass and volume, the energy there of when rebounding is relatively small, and it is considered that it is difficult for Kr to get into the W film. However, since Kr gas is at least 100 times more expensive than Ar gas, it is difficult to use the Kr gas in the semiconductor manufacturing process.

On the other hand, if the pressure is increased, since the energy of Ar atoms rebounding by the collision in a space is lost, defects due to the rebounding Ar atoms hardly occur; however, the energy of sputtered atoms also decreases, and the atoms reaching the film surface on the substrate do not contribute to the diffusion. As a result, there is formed a film having many defects and an orientation that is not aligned. Further, by increasing the pressure, the discharge current is increased, but there occurs a phenomenon in which the sputtered atoms diffuse toward the chamber wall by collision scattering. In the conventional technology in which the distance between the target and the substrate is large, since the deposition rate on the substrate is generally reduced due to this phenomenon, it is not preferable in terms of deposition efficiency.

On the other hand, there is a method of inducing the surface diffusion of W particles by supplying high frequency power to the substrate and injecting Ar ions into the substrate at a constant energy to give the kinetic energy to the film surface. However, in the conventional magnetron sputtering apparatus, since the distance between the target and the substrate is long and a discharge is caused under low pressure, the density of the plasma in the vicinity of the substrate is low and it is necessary to convert the Ar ions into high-energy ions. Accordingly, the high frequency power of high potential should be applied to the substrate. Thus, a negative potential than necessary is generated in the substrate, and the Ar ions having excessive energy are pulled onto the substrate. Consequently, as described above, the Ar ions rush into the deposited W film to cause damage to the film. It is also possible to increase the pressure in order to reduce the applied high frequency power, but the deposition efficiency is lowered as described above.

As described above, in the conventional magnetron sputtering apparatus in which the distance between the target 13 and the substrate is 50 mm to 100 mm, in case of depositing high melting point metal such as tungsten (W), it is difficult to meet all conditions of high-speed deposition, deposition efficiency, target utilization efficiency, low resistance, and good film quality. This problem also occurs in the sputter deposition of other types of high melting point metal such as tantalum (Ta), titanium (Ti), molybdenum (Mo), ruthenium (Ru), hafnium (Hf), cobalt (Co) and nickel (Ni).

### SUMMARY OF THE INVENTION

In view of the above, the present invention provides a technique capable of improving the deposition efficiency and the utilization efficiency of a target while ensuring the in-plane uniformity of the deposition rate. The present invention also provides a technique capable of forming a low resistance film at a high deposition rate.

In accordance with an aspect of the present invention, there is provided a magnetron sputtering apparatus in which a target is disposed to face a substrate to be processed, which is placed in a vacuum chamber, and magnets are provided on a rear side of the target, the apparatus including: a power supply unit for applying a voltage to the target; a magnet array body including a magnet group arranged on a base body; and a rotating mechanism for rotating the magnet array body around an axis perpendicular to the substrate, wherein in the magnet array body, N poles and S poles constituting the magnet group are arranged to be spaced from each other along a surface facing the target such that a plasma is generated based on a drift of electrons by a cusp magnetic field, magnets located on the outermost periphery of the magnet group are arranged in a line to prevent the electrons from being released from constraint of the cusp magnetic field and jumping out of the cusp magnetic field, and a distance between the target and the substrate during sputtering is equal to or less than 30 mm.

Here, arranging in a line includes, in addition to a configuration in which a magnet is formed in a strip shape such as a straight or curved line shape, and a configuration in which magnets are arranged in a strip shape such as a straight or curved line shape, a configuration in which magnets are arranged to be spaced from each other in a strip shape such as a straight or curved line shape to prevent electrons from being released from the constraint of the cusp magnetic field and jumping out of the cusp magnetic field.

In accordance with another aspect of the present invention, there is provided a magnetron sputtering apparatus in which a target is disposed to face a substrate to be processed, which is placed in a vacuum chamber, magnets are provided on a rear side of the target, and a magnetron sputtering process is performed on the substrate which is a semiconductor wafer having a diameter of 300 mm, the apparatus including: a power supply unit for applying a voltage to the target; a magnet array body including a magnet group arranged on a base body; and a rotating mechanism for rotating the magnet array body around an axis perpendicular to the substrate, wherein in the magnet array body, N poles and S poles constituting the magnet group are arranged to be spaced from each other along a surface facing the target such that a plasma is generated based on a drift of electrons by a cusp magnetic field, magnets located on the outermost periphery of the magnet group are arranged in a line to prevent the electrons from being released from constraint of the cusp magnetic field and jumping out of the cusp magnetic field, and if R (mm) is a diameter of the target and TS (mm) is a distance between the target and the substrate, the distance TS is set to satisfy

(TS′/R)×100(%)=0.0006151R²−0.5235R+113.4, and

TS≦1.1TS′.

In accordance with still another aspect of the present invention, there is provided a magnetron sputtering apparatus in which a target is disposed to face a substrate to be processed, which is placed in a vacuum chamber, magnets are provided on a rear side of the target, and a magnetron sputtering process is performed on the substrate which is a semiconductor wafer having a diameter of 450 mm, the apparatus including: a magnet array body including a magnet group arranged on a base body; and a rotating mechanism for rotating the magnet array body around an axis perpendicular to the substrate, wherein in the magnet array body, N poles and S poles constituting the magnet group are arranged to be spaced from each other along a surface facing the target such that a plasma is generated based on a drift of electrons by a cusp magnetic field, magnets located on the outermost periphery of the magnet group are arranged in a line to prevent the electrons from being released from constraint of the cusp magnetic field and jumping out of the cusp magnetic field, and if R (mm) is a diameter of the target and TS (mm) is a distance between the target and the substrate, the distance TS is set to satisfy

(TS′/R)×100(%)=0.0003827R²−0.4597R+139.5, and

TS≦1.1TS′.

In accordance with still another aspect of the present invention, there is provided a magnetron sputtering method using the magnetron sputtering apparatus described above. In the method, a metal film is deposited on the substrate under the condition that a process pressure is set to be equal to or greater than 13.3 Pa (100 mTorr), and an input power density obtained by dividing an input power to the target by an area of the target is set to be equal to or greater than 3 W/cm².

### BRIEF DESCRIPTION OF THE DRAWINGS

The objects and features of the present invention will become apparent from the following description of embodiments, given in conjunction with the accompanying drawings, in which:

FIG. 1 is a longitudinal cross-sectional view showing a magnetron sputtering apparatus in accordance with an embodiment of the present invention;

FIG. 2 is a plan view showing an example of a magnet array body provided in the magnetron sputtering apparatus;

FIG. 3 is a sectional view showing the magnet array body;

FIG. 4 is a perspective view showing an example of a magnet which is provided in the magnet array body;

FIG. 5 is a perspective view showing an example of a magnet which is provided in the magnet array body;

FIG. 6 is a plan view showing the magnet array body;

FIG. 7 is a plan view showing another example of the magnet array body;

FIG. 8 is a plan view showing still another example of the magnet array body;

FIG. 9 is a characteristic diagram showing a relationship between the in-plane uniformity of the deposition rate, the deposition efficiency and the distance between the target and the substrate;

FIG. 10 is a plan view showing still another example of the magnet array body;

FIG. 11 is a plan view showing still another example of the magnet array body;

FIG. 12 is a plan view showing still another example of the magnet array body;

FIG. 13 is a plan view showing still another example of the magnet array body;

FIG. 14 is a plan view showing still another example of the magnet array body;

FIG. 15 is a plan view showing still another example of the magnet array body;

FIG. 16 is a characteristic diagram showing the results of Example 1;

FIG. 17 is a characteristic diagram showing the results of Example 2;

FIG. 18 is a characteristic diagram showing the results of Example 2;

FIG. 19 is a characteristic diagram showing the results of Example 3;

FIG. 20 is a characteristic diagram showing the results of Example 4;

FIG. 21 is a characteristic diagram showing the results of Example 5;

FIG. 22 is a plan view showing still another example of the magnet array body;

FIG. 23 is an enlarged plan view of the magnet array body of FIG. 22;

FIG. 24 is a side view showing the magnet array body;

FIG. 25 is a side view showing the magnet array body;

FIG. 26 is a plan view showing still another example of the magnet array body;

FIG. 27 is a graph showing the results of a simulation of the film thickness distribution;

FIG. 28 is a graph showing the results of a simulation of the film thickness distribution;

FIGS. 29A and 29B are graphs showing the results of a simulation of the deposition rate;

FIG. 30 is a characteristic diagram showing the results of Example 6;

FIG. 31 is a characteristic diagram showing the results of Example 7;

FIG. 32 is a characteristic diagram showing the results of Example 8;

FIG. 33 is a longitudinal cross-sectional view showing a conventional magnetron sputtering apparatus;

FIG. 34 is a plan view showing a magnet body used in the conventional magnetron sputtering apparatus; and

FIG. 35 is a vertical cross-sectional view for explaining an effect of the conventional magnetron sputtering apparatus.

### DETAILED DESCRIPTION OF THE EMBODIMENTS

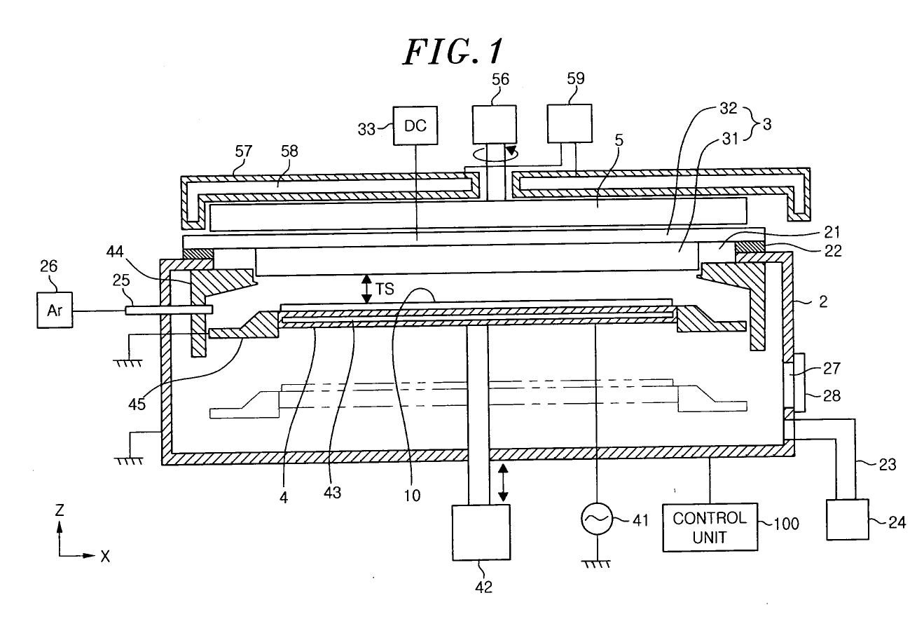

A magnetron sputtering apparatus in accordance with an embodiment of the present invention will be described with reference to the accompanying drawings. FIG. 1 is a longitudinal cross-sectional view showing an example of the magnetron sputtering apparatus, and reference numeral 2 in the figure denotes a vacuum chamber which is formed of, e.g., aluminum (Al) and is grounded. In the vacuum chamber 2, a ceiling has an opening 21, and a target electrode 3 is provided so as to close the opening 21. The target electrode 3 is configured by bonding a target 31 formed of a film forming material such as tungsten (W) to the lower surface of a conductive base plate 32 formed of, e.g., copper (Cu) or aluminum (Al). The target 31 is configured to have a circular shape in a plane view, and its diameter is set to be greater than that of a semiconductor wafer (hereinafter referred to as “wafer”) as a substrate to be processed, e.g., 400 to 450 mm.

The base plate 32 is formed to be larger than the target 31, and is provided such that a peripheral region of the lower surface of the base plate 32 is placed around the opening 21 of the vacuum chamber 2. In this case, an annular insulating member 22 is provided between the vacuum chamber 2 and the peripheral portion of the base plate 32. Thus, the target electrode 3 is fixed to the vacuum chamber 2 in a state of being electrically isolated from the vacuum chamber 2. Further, a negative DC voltage is applied to the target electrode 3 by a power supply unit 33.

In the vacuum chamber 2, there is provided a mounting part 4 which horizontally mounts a wafer 10 so as to face the target electrode 3 in parallel. The mounting part 4 is configured as an electrode (counter electrode) made of, e.g., aluminum. A high frequency power supply unit 41 for supplying a high frequency power is connected to the mounting part 4. The mounting part 4 is configured to be vertically movable between a transfer position for loading/unloading the wafer 10 into/from the vacuum chamber 2 and a processing position at the time of sputtering by a lifting mechanism 42. At the processing position, e.g., a distance TS between the upper surface of the wafer 10 on the mounting part 4 and the lower surface of the target 31 is set to range, e.g., 10 mm to 30 mm.

Further, a heater 43 forming a heating mechanism is embedded in the mounting part 4 to heat the wafer 10 to, e.g., 400° C. Further, protruding pins (not shown) for delivering the wafer 10 between the mounting part 4 and an external transfer arm (not shown) are provided in the mounting part 4.

In the vacuum chamber 2, an annular chamber shield member 44 is provided to surround the lower side of the target electrode 3 along the circumferential direction, and an annular holder shield member 45 is provided to surround the side of the mounting part 4 along the circumferential direction. These are provided in order to suppress the adhesion of sputtered particles to the inner wall of the vacuum chamber 2, and are formed of a conductive material such as aluminum or an alloy including aluminum as a base material. The chamber shield member 44 is connected to, e.g., the inner wall of the ceiling of the vacuum chamber 2, and is grounded through the vacuum chamber 2. Further, the holder shield member 45 is grounded such that the mounting part 4 is grounded via the holder shield member 45.

Further, the vacuum chamber 2 is connected to a vacuum pump 24 that is a vacuum exhaust mechanism through an exhaust passage 23, and is connected to an inert gas (e.g., Ar gas) supply source 26 through a supply line 25. In the figure, reference numeral 27 denotes a transfer port of the wafer 10, which is configured to be freely opened and closed by a gate valve 28.

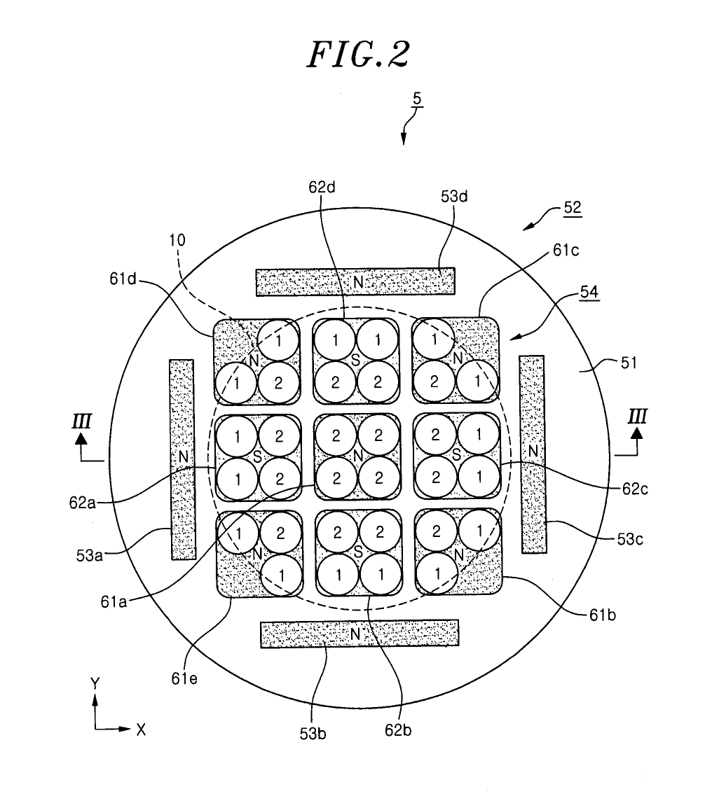

At the upper side of the target electrode 3, a magnet array body 5 is provided to be contiguous with the target electrode 3. The magnet array body 5 is configured by arranging a magnet group 52 on a base body 51 formed of a high permeability material such as iron (Fe) as shown in FIG. 2 and FIG. 3 (sectional view taken along line of FIG. 2). The base body 51 is provided to face the target 31, and as shown in FIG. 2, is formed to have a circular shape in a plane view. Further, the diameter of the base body 51 is set to be greater than that of the target 31, e.g., to a value about 60 mm greater than the target diameter. FIG. 2 is a plane view of the magnet group 52 when seen from the target 31.

The magnet array body 5 is configured such that N poles and S poles constituting the magnet group are arranged to be spaced from each other along the surface facing the target 31 as will be described later so as to generate a plasma over the entire projection area of the wafer 10 based on the drift of electrons by a cusp magnetic field when at rest, and return magnets 53 are provided at the outermost periphery of the magnet group 52. The return magnets 53 are arranged in a line as will be described below so as to prevent the electrons from being released from restraint by the cusp magnetic field and jumping out of the cusp magnetic field.

In the magnet group 52, when a magnet group located inwardly of the return magnets 53 is referred to as “inside magnet group 54,” and magnets located in the outermost periphery of the inside magnet group 54 is referred to as “outside magnets,” the inside magnet group 54 is configured by arranging a plurality of magnets 6 (61, 62) in a matrix. As shown in FIG. 2, the magnets 6 (61, 62) are arranged in a matrix of n columns×m rows, e.g., 3 columns×3 rows in a lateral direction (X direction in FIGS. 1 and 2) and in a transverse direction (Y direction in FIGS. 1 and 2) of the target 31 and are arranged such that the adjacent magnets 6 (61, 62) have different polarities.

In this example, the central magnet 61a has an N pole, and S-pole magnets 62a to 62d are arranged to be spaced from each other respectively on both sides of the lateral direction and on both sides of the transverse direction of the magnet 61a. Here, the polarity in the present invention refers to the polarity facing the target 31, i.e., the polarity when viewed from the target 31. Accordingly, the magnet 61a has an N pole facing the target 31 and an S pole facing the base body 51.

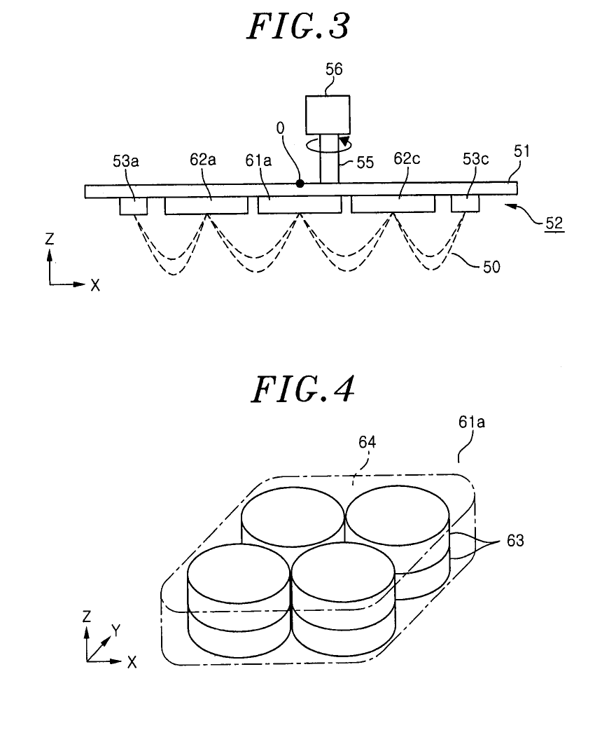

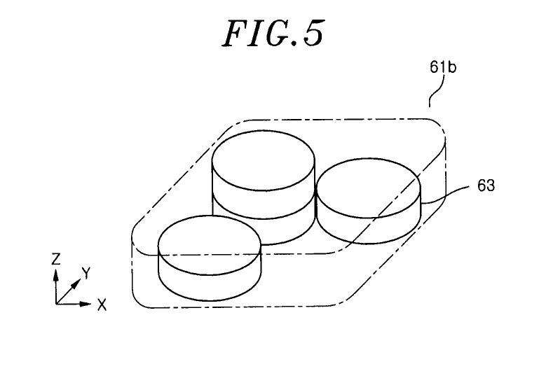

These magnets 61 and 62 are configured to be divided into a plurality of magnet elements. As shown in FIG. 4, magnet elements 63 are formed in, e.g., a cylindrical shape. The magnet 61a is configured as a collection of total eight magnet elements 63 such that two magnet elements 63 are arranged in the lateral direction, two magnet elements 63 are arranged in the transverse direction, and the magnet elements are stacked in two stages. The magnet elements 63 have a diameter of, e.g., 20 to 30 mm and a thickness of, e.g., 10 to 15 mm, and one magnet element has a surface magnetic flux density of about 2 to 3 kG. These magnet elements 63 are accommodated in a case body 64 having a substantially square shape in a plane view, the case body 64 being fixed to the lower surface of the base body 51.

These magnets 61 and 62 are provided such that the adjacent sides of the case bodies 64 are parallel to each other respectively in the lateral direction and the transverse direction, and are arranged such that the adjacent case bodies 64 are equidistant from each other. In other words, when describing using the central magnet 61a as an example, the magnets are provided such that a separation distance L2 between the magnet 61a and each of the magnets 62a and 62c adjacent to the magnet 61a in the lateral direction and a separation distance L1 between the magnet 61a and each of the magnets 62b and 62d adjacent to the magnet 61a in the transverse direction are equal to each other. Thus, the magnets 61 and 62 are arranged in a matrix such that the centers of the magnets 62a to 62d are on the same radius, and the centers of the magnets 61b to 61e are on the same radius when viewed from the center of the array of the inside magnet group 54. In this example, the center of the array of the inside magnet group 54 corresponds to the center O of the base body 51.

Further, the inside magnet group 54 is configured such that the number of the N-pole magnet elements 63 is equal to the number of the S-pole magnet elements 63, and the number of the magnet elements 63 is equal in the magnets 62a to 62d (magnets 61b to 61e) whose centers are on the same radius when viewed from the center O of the array. Also, the inside magnet group 54 is set such that a magnetic force decreases toward the outside magnets (by adjusting the number of the magnet elements 63) when viewed from the center O of the array. Since the magnets 61 and 62 are configured to be divided into a plurality of magnet elements 63, the magnetic force of the magnets 61 and 62 is adjusted by the number of the magnet elements 63 thereof.

Here, the number written in each of the magnet elements 63 in FIG. 2 represents the number of the magnet elements 63 stacked in a height direction of the magnet group (Z direction in FIG. 4). For example, in case of the outside magnet 61b of FIG. 5, the outside magnet 61b is configured as a combination of four magnet elements 63.

Thus, the inside magnet group 54 of this example includes twenty-four N-pole magnet elements 63 and twenty-four S-pole magnet elements 63. Further, when viewed from the center O of the array, the magnet 61a located in the center has eight magnet elements 63, each of the magnets 62a to 62d located on the same radius has six magnet elements 63, and each of the magnets 61b to 61e located on the same outermost radius has four magnet elements 63. In this way, the magnetic force of the outside magnet located in the outermost periphery of the inside magnet group 54 is set to be smaller than that of the magnet located inwardly of the corresponding outside magnet.

With regard to the return magnets 53a to 53d, when illustrating the return magnet 53d as an example, the return magnet 53d is formed such that the electrons drifting around the magnet 62d located in the center of the outside magnets return to the inside without jumping out of the magnet group 52 from the gap of the magnet group 52 when the magnet group 52 is viewed in a plane. Accordingly, the return magnet 53d is arranged in a line shape and, in this case, is formed in a linear shape (strip shape extending in a straight line) when seen in a plane. Further, the return magnet 53d is formed such that its length is greater than the length of the magnet 62d, and both longitudinal ends thereof are located at positions corresponding to the outside magnets 61c and 61d adjacent to both sides of the magnet 62d. Further, the return magnet 53d is set to have a polarity different from that of the magnet 62d located in the center of the outside magnets.

Further, the return magnets 53a and 53c respectively disposed on both sides in the lateral direction of the inside magnet group 54 are provided such that its length direction is in parallel to the transverse direction. The return magnets 53b and 53d respectively disposed on both sides in the transverse direction of the inside magnet group are provided such that its length direction is in parallel to the lateral direction. These four return magnets 53a to 53d are provided to have the same separation distance L3 between each of the return magnets 53a to 53d and the corresponding outside magnets 61 and 62 located in the outermost periphery of the inside magnet group 54.

In the present embodiment, the magnet group 52 is configured such that the position of the periphery of the wafer 10 is located inwardly of a moving region of a group of drifting electrons. Further, the surface magnetic flux densities of the return magnets 53 and the inside magnet group 54 have been adjusted respectively to maintain a balance between the magnetic flux of each return magnet 53 and the magnetic flux of the corresponding outside magnets 61 and 62 of the inside magnet group 54.

Further, the intensity of the horizontal magnetic field (magnetic flux density) is preferably set to, e.g., 100 to 300 G in order to obtain a stable discharge. This magnetic flux density is designed appropriately according to the size of the magnets 61 and 62, the surface magnetic flux density of the magnets 61 and 62, the number of the arranged magnets 61 and 62, the distance between the magnets 61 and 62, the number of the magnet elements 63, the distance between the magnet elements 63, the size of the outside magnets, and the distance between the outside magnets and the inside magnet group 54, the rotation eccentricity which will be described later, and the like.

Further, as will be described later, ionization occurs in each of the return magnets 53 and the inside magnet group 54. The strength of the ionization is different in the return magnets 53 and the inside magnet group 54, but it is possible to control the strength of ionization by adjusting the surface magnetic flux density and/or the size of the return magnets 53 and the separation distance L3 between the return magnets and the inside magnet group 54.

Further, if there is a separation portion between the return magnets 53 and the inside magnet group 54 in an area extending 50 mm outward from the outer edge of the wafer 10, it is obvious from the simulation that the uniformity of the deposition rate is good, and this configuration is preferable. Further, if the position of the outer edge of the target 31 is set to be in the separation portion between the return magnets 53 and the inside magnet group 54, the horizontal magnetic field by the return magnets 53 covers the outer periphery of the target 31, and it is possible to form the erosion on the entire surface of the target. If the forming region of the magnet is larger than the target 31, abnormal discharge may occur, but it is understood that it is possible to prevent abnormal discharge by keeping the balance between the magnetic flux of the return magnets 53 and the magnetic flux of the magnets 61 and 62 of the inside magnet group 54.

As described above, by adjusting various conditions such as the array spacing and the size of the magnet elements, the magnet array body 5 is designed such that a uniform magnetic field is formed directly below the target 31. In this case, the example shown in FIG. 2 represents the relative sizes of the magnet group 52, the wafer 10 and the base body 51. In this way, the outer edge of the wafer 10 is located inside the forming region of the magnet group 52. However, the magnet group 52 in the example shown in FIG. 2 is one of configuration examples, and the numbers of the return magnets 53 and the magnets 61 and 62 that are installed are increased or decreased appropriately according to the size of the wafer 10.

As one design example, the return magnets 53 may have a cross section size of, e.g., 10 mm×20 mm, a length of, e.g., 120 mm, and a surface magnetic flux density of 2 to 3 kG, but by adjusting the size or the number of stacked magnets, it is possible to optimize the magnetic force with respect to the outside magnets of the inside magnet group 54. Further, in the inside magnet group 54, each of the separation distance L1 between the magnets 61 and 62 in the lateral direction and the separation distance L2 between the magnets 61 and 62 in the transverse direction is set to, e.g., 5 to 10 mm. The separation distance L3 between each of the return magnets 53 and the corresponding magnets 61 and 62 of the outermost periphery of the inside magnet group 54 is set to, e.g., 5 to 30 mm.

Further, the magnets 61, 62 and 53 constituting the inside magnet group 54 are set to have the same thickness.

Accordingly, it is configured such that the lower surfaces of the magnets 61, 62 and 53 have the same height position. Further, a distance between the lower surfaces of the magnets 61, 62 and 53 and the upper surface of the target 31 is set to, e.g., 15 to 40 mm. In this case, by placing a dummy body made of iron and having the same shape as the magnet elements 63 on the base body 51, it is possible to allow the lower surfaces of the magnets to have the same height. Since iron has a high permeability, the magnetic flux toward the base body 51 does not diffuse. Accordingly, the magnetic flux toward the target electrode 3 is the same as that when there is no dummy body. An advantage in this case is that it is possible to adjust the magnetic flux toward the target electrode 3 while maintaining the entire balance.

The upper surface of the base body 51 of the magnet array body 5 is connected to a rotating mechanism 56 through a rotation shaft 55. By the rotating mechanism 56, the magnet array body 5 is configured to be rotatable around the axis perpendicular to the wafer 10. In this example, as shown in FIG. 3, the rotation shaft 55 is provided at a position eccentric from the center O of the base body 51 by e.g., 20 to 30 mm.

Around the magnet array body 5, a cooling jacket 57 forming a cooling mechanism is provided to cover the upper and side surfaces of the magnet array body 5 in a state of ensuring a rotation region of the magnet array body 5. A passage 58 of a cooling medium is formed in the cooling jacket 57. It is configured to cool the magnet array body 5 and the target electrode 3 through the magnet array body 5 by circulating and supplying a cooling medium, e.g., cooling water, which is adjusted to a predetermined temperature, in the passage 58 from a cooling medium supply unit 59.

The magnetron sputtering apparatus having the above configuration includes a control unit 100 for controlling the operation for supplying power from the power supply unit 33 and the high frequency power supply unit 41, the Ar gas supply operation, the elevating operation of the mounting part 4 by the lifting mechanism 42, the rotating operation of the magnet array body 5 by the rotating mechanism 56, the exhaust operation of the vacuum chamber 2 by the vacuum pump 24, the heating operation by the heater 43 or the like. The control unit 100 includes a computer having, e.g., a storage unit and a CPU (not shown). The storage unit stores a program including a step (instruction) group for control necessary for the deposition on the wafer 10 by the magnetron sputtering apparatus. This program is stored in a storage medium such as a hard disk, compact disk, magnet optical disk, and memory card, and is installed on the computer therefrom.

Next, there will be described an effect of the magnetron sputtering apparatus described above. First, the transfer port 27 of the vacuum chamber 2 is opened and the mounting part 4 is placed to a delivery position. Then, the wafer 10 is delivered to the mounting part 4 by an cooperation of the protruding pins and the external transfer mechanism (not shown). Then, the transfer port 27 is closed and the mounting part 4 is raised to a processing position. Also, while introducing Ar gas into the vacuum chamber 2, the vacuum chamber 2 is evacuated by the vacuum pump 24 such that a predetermined vacuum level, e.g., 1.46 to 13.3 Pa (11 to 100 mTorr) is maintained in the vacuum chamber 2. Meanwhile, while rotating the magnet array body 5 by the rotating mechanism 56, a negative DC voltage of, e.g., 100 W to 3 kW is applied to the target electrode 3 from the power supply unit 33, and a high frequency voltage of about several hundred KHz to hundred MHz and about 10 W to 1 kW is applied to the mounting part 4 from the high frequency power supply unit 41. Further, the cooling water is kept at all times to flow through the passage 58 of the cooling jacket 57.

When a DC voltage is applied to the target electrode 3, the Ar gas is ionized by the electric field to generate electrons. Meanwhile, by the magnet group 52 of the magnet array body 5, as shown in FIG. 3, a cusp magnetic field 50 is formed between the magnets 61 and 62 of the inside magnet group 54, and between the outside magnets of the inside magnet group 54 and the return magnets 53. The cusp magnetic field 50 is continuous to form a horizontal magnetic field in the vicinity of the surface (to be sputtered) of the target 31.

Thus, the electrons are accelerated to drift by E×B due to the horizontal magnetic field B and the electric field E in the vicinity of the target 31. Then, the accelerated electrons having sufficient energy collide with the Ar gas to cause the ionization, thereby forming a plasma. Ar ions in the plasma sputter the target 31. Further, secondary electrons generated by sputtering are captured in the horizontal magnetic field to contribute to the ionization again. Thus, the electron density becomes higher, and the plasma has a high density.

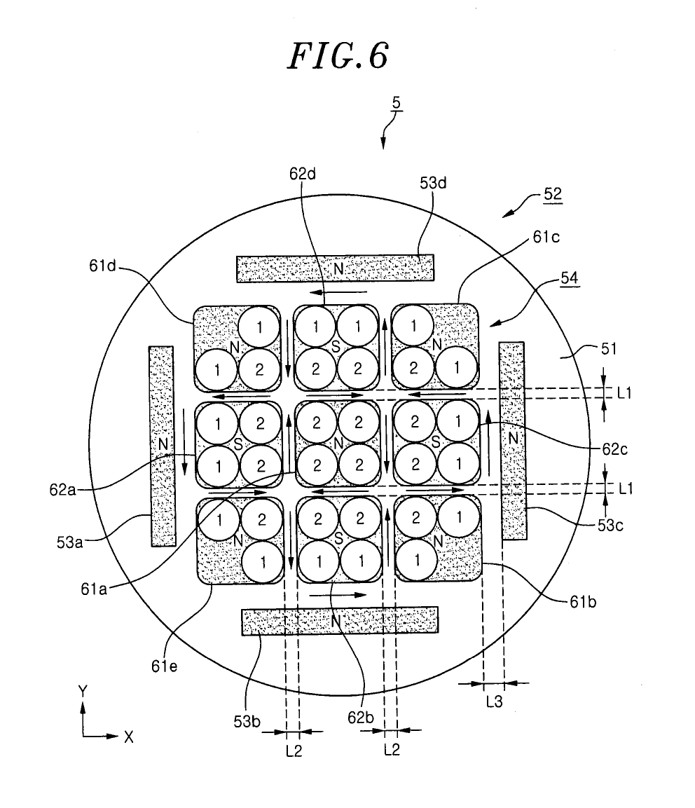

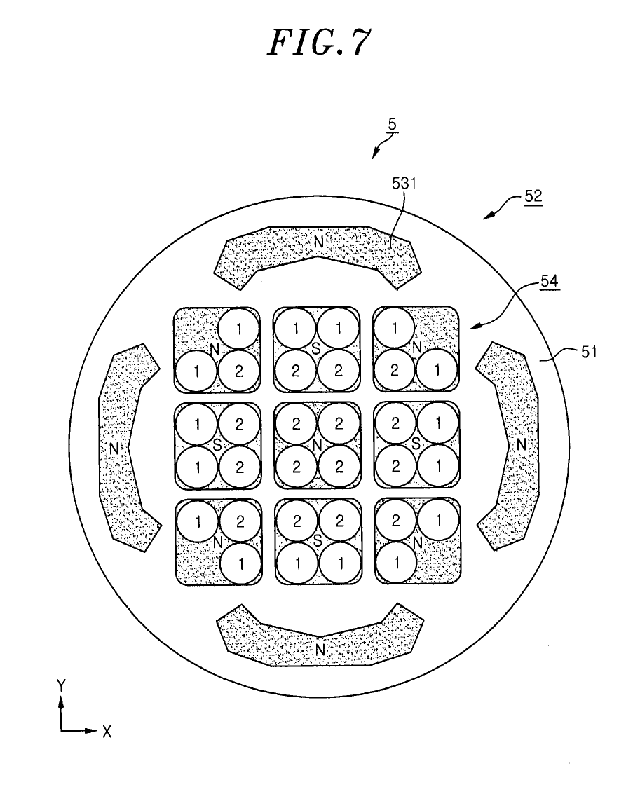

The direction of the drift of the electrons is schematically shown in FIG. 6. For example, when focusing on the N-pole magnet 61a in the center of the inside magnet group 54, the electrons drift to revolve around the magnet 61a clockwise. The electrons drift to revolve around the S-pole magnets 62a, 62b, 62c, 62d counterclockwise.

According to the layout of the magnet group 52, the position of the periphery of the wafer 10 is set to be located inwardly of a moving region of the drifting electrons. Accordingly, when the magnet array body 5 is stationary, the plasma is generated over the entire projection area of the wafer 10 on the basis of the drift of electrons by the cusp magnetic field.

When describing the return magnet 53d as an example, the return magnet 53d is formed into a strip extending in a straight line in the horizontal direction as described above, and has the separation distance L3 from the outside magnet 62d in the outermost periphery of the inside magnet group 54. Further, both longitudinal ends of the return magnet 53d are located at positions corresponding to the magnets 61c and 61d adjacent to the magnet 62d.

Thus, when viewed from the electrons drifting between the magnet 62d and the magnet 61c, the magnet 53d exists to stand on the front side in the traveling direction. Further, since the magnetic flux of the cusp magnetic field derived from the magnet 53d is combined with the magnetic flux of the cusp magnetic field derived from the magnet 62d, the electrons drifting between the magnet 62d and the magnet 61c move along the cusp magnetic field as they are, and make a curve to the left. Then, when reaching a portion between the magnet 62d and the magnet 61d, the electrons are constrained by the cusp magnetic field between them, and make a curve to the left, thereby returning to the region of the inside magnet group 54. In this way, by providing the return magnets 53, the electrons are prevented from jumping out of the cusp magnetic field by the constraint of the cusp magnetic field. Thus, electron loss is suppressed and the electron density becomes high.

On the other hand, if there is no return magnet 53, in the outer periphery of the inside magnet group 54, as described above, there exists an open end where the vector direction of E×B is toward the outside of the target 31. For this reason, the electrons drifting between the magnet 62d and the magnet 61c are released from the constraint of the cusp magnetic field and jump to the outside of the magnet group 52 because there is no cusp magnetic field on the front side in the drifting direction. Thus, since the electrons jump out from the magnet of the outermost periphery of the inside magnet group 54, electron loss increases and it is impossible to increase the electron density. Also, since the electron density in the outer periphery becomes smaller, the in-plane uniformity of the electron density deteriorates.

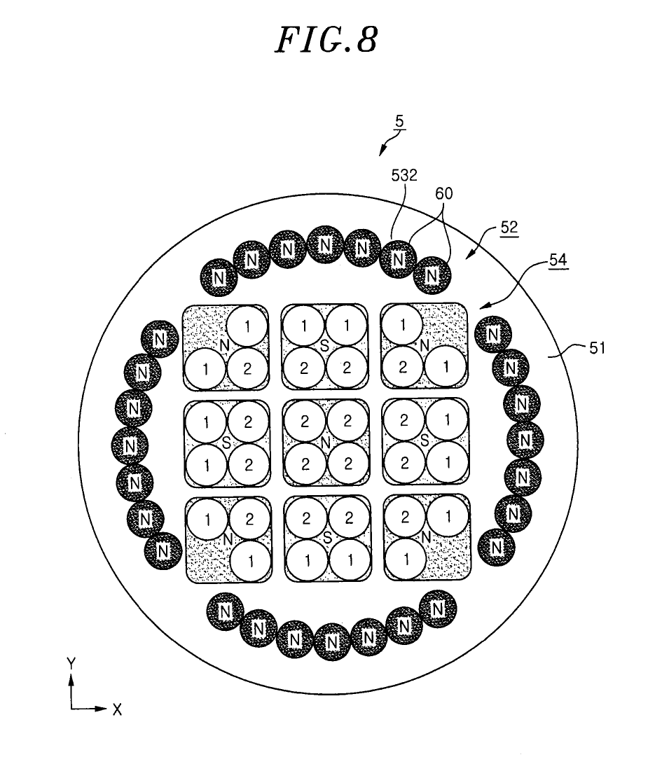

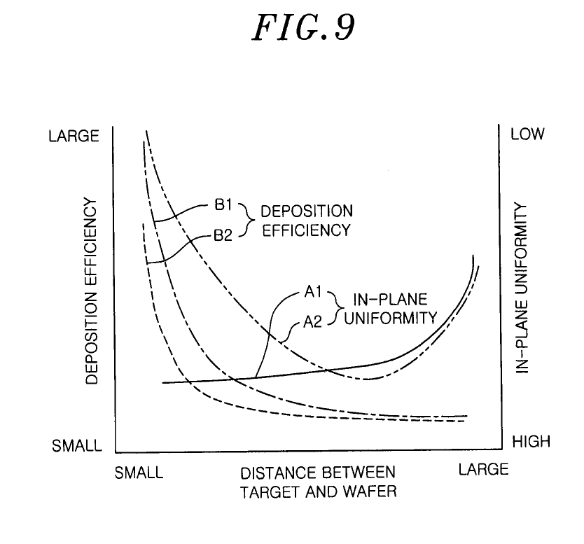

FIGS. 6 to 8 are plan views of the magnet array body 5 when seen from the target 31. As described above, since the return magnets 53 serve to prevent the electrons from jumping out of the magnet group 52 from the gap of the magnet group 52 and return the electrons to the inside, the return magnets 53 may be arranged in a line to exert the effect. When describing the return magnet 53d provided corresponding to the outside magnet 62d as an example, the present inventors have found that the effect can be obtained if the return magnet 53d has a polarity different from the outside magnet 62d and is arranged in a straight or curved line to face the magnet 62d such that both ends of the return magnet 53d are located at positions corresponding to the outside magnets 61c and 61d adjacent to both sides of the outside magnet 62d. Therefore, return magnets 531 having a substantially arc shape in a plane view may be used as shown in FIG. 7, and return magnets 532 may be configured by arranging a plurality of point-shaped magnets 60 in a line as shown in FIG. 8. In this case, in addition to a case where the point-shaped magnets 60 are arranged in contact with each other, the point-shaped magnets 60 may be arranged to be spaced slightly from each other as long as they serve to prevent the electrons from jumping out and return them to the inside. For example, in case of using the point-shaped magnets, point-shaped magnets, each having a diameter of 15 to 25 mm, a height of 10 to 15 mm, and a surface magnetic flux density of 2 to 3 kG may be used. In this case, the magnetic force can be adjusted by the number of magnets arranged in the length direction and/or the number of stacked magnets, and magnets having different magnetic force strengths may be arranged in order to adjust the magnetic force.

In this way, the electrons are accelerated to revolve around all the magnets 61 and 62 as well as one of the magnets 61 and 62, and repeat the ionization and collision with the Ar gas. In this case, the ionization also occurs between the return magnets 53 and the inside magnet group 54, and secondary electrons generated by this ionization also drift and enter the region of the inside magnet group 54 to contribute to the ionization of the entire region in which the magnet group 52 is formed. As a result, a high density plasma can be generated with high in-plane uniformity directly below the target 31. Further, since it is possible to ensure the balance of the magnetic flux while suppressing the divergence of the magnetic flux in the outermost periphery of the inside magnet group 54, the in-plane uniformity of plasma density becomes higher also from this point of view.

Thus, by repeating the ionization of the Ar gas, Ar ions are generated and the target 31 is sputtered by the Ar ions. Accordingly, tungsten particles released from the surface of the target 31 scatter into the vacuum chamber 2, and the particles adhere to the surface of the wafer 10 on the mounting part 4, thereby forming a thin film of tungsten on the wafer 10. Further, the particles deviated from the wafer 10 are attached to the chamber shield member 44 or the holder shield member 45. In this case, since a high frequency power is supplied to the mounting part 4, the Ar ions are attracted and incident on the wafer 10, and a dense thin film with a low resistance is formed by a synergistic action with heating by the heater 43.

The erosion of the target 31, as described above, is formed in an intermediate portion (center or near the center) between the magnets having different poles. However, in the above-described magnet array body 5, since the magnets 61 and 62 are arranged in a matrix, there are many places where erosion occurs, and the erosion is formed periodically over the entire surface of the target 31. In addition, as described above, since it is possible to make the plasma density more uniform over the entire projection area of the wafer 10, the degree of progression of the erosion becomes uniform, and the in-plane uniformity becomes higher also from this point of view.

In this case, in order to further increase the uniformity of erosion, the magnet array body 5 is rotated around the vertical axis by the rotating mechanism 56. When seeing the plasma density microscopically, the non-uniform plasma density is formed based on the horizontal magnetic field, but the plasma density becomes uniform by rotating the magnet array body 5. In addition, in this embodiment, since the magnet array body 5 is rotated around the position eccentric from the center of the base body 51, as will be clear from embodiments to be described later, the uniformity of the distribution of the deposition rate becomes further higher.

In other words, in the magnet array body 5, the horizontal magnetic flux density is formed to be uniformly distributed in the surface of the target 31, and the erosion occurs in the intermediate portion between the magnets 61 and 62. However, since there is no horizontal magnetic field and ionization does not happen in the cusp portion immediately below the magnets 61 and 62, sputtering is difficult to occur. For this reason, the deposition rate immediately below the magnets 61 and 62 is smaller than the other portions, and the deposition rate distribution has a shape in which small irregularities are present periodically. Therefore, when eccentrically rotating the magnet array body 5, the irregularities are offset, and it is possible to obtain the more uniform deposition rate distribution.

In this case, if the magnet array body 5 is formed such that portions causing the erosion occur alternately in the circumferential direction, the erosion is equalized temporally. If the magnet array body 5 is formed such that there are many rotation targets of the erosion, since it is possible to achieve a uniform distribution of the deposition rate even though the number of revolutions is small, it is advantageous when a film is formed in a short time at high speed.

Further, since the in-plane uniformity of erosion is high as described above, in the present embodiment, the sputtering process is performed in a state where the wafer 10 and the target 31 are made to be close to each other such that the distance between the wafer 10 and the target 31 is equal to or less than 30 mm. That is, this is because, since the shape of the erosion is reflected in the distribution of the deposition rate, it is possible to obtain a high deposition rate distribution uniformity even though the wafer 10 is close to the target 31 if the uniformity of erosion is high. In this case, when the wafer 10 is separated away from the target 31, as will be clear from embodiments to be described later, the deposition rate in the outer periphery of the wafer 10 is lowered. This is because the sputtered particles on the outer periphery of the target 31 scatter to the outside of the wafer 10, thereby reducing the deposition efficiency.

Thus, in the present embodiment, in order to ensure the in-plane uniformity of the deposition rate, it is necessary to perform the sputtering process in a state where the wafer 10 and the target 31 are made to be close to each other such that the distance between the wafer 10 and the target 31 is equal to or less than 30 mm. However, if the target 31 and the wafer 10 are made to be excessively close to each other, a plasma generating space becomes too small, and the discharge is less likely to occur. Accordingly, it is preferable that the distance between the target 31 and the wafer 10 is set to at least 10 mm.

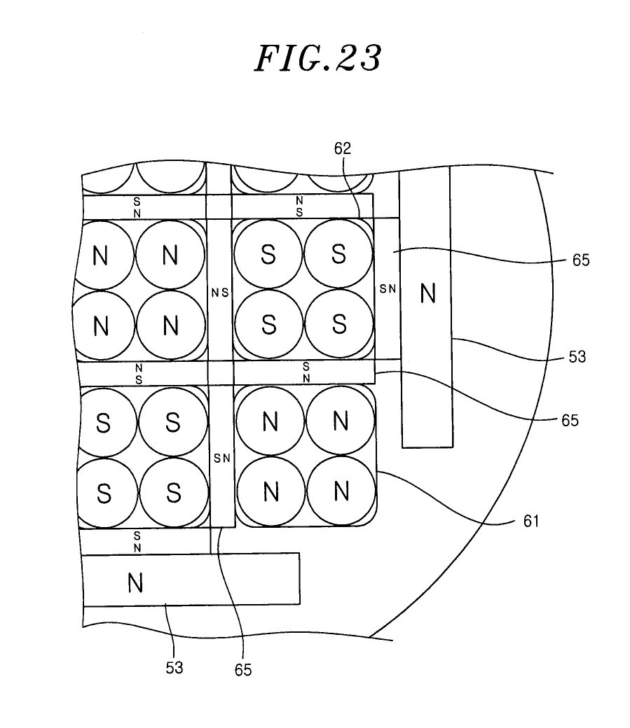

Further, since the wafer 10 is located directly below the target 31, the particles sputtered from the target 31 promptly adhere to the wafer 10. For this reason, many sputtered particles contribute to the formation of the thin film of the wafer 10, thereby enhancing the deposition efficiency. FIG. 9 shows a relationship between the distance between the target 31 and the wafer 10 and the deposition efficiency, and a relationship between the distance between the target 31 and the wafer 10 and the in-plane uniformity of the deposition rate. In FIG. 9, the horizontal axis represents the distance between the target 31 and the wafer 10, the left vertical axis represents the deposition efficiency, and the right vertical axis represents the in-plane distribution of the deposition rate. With regard to the deposition efficiency, the configuration of the present embodiment is represented by solid line μl, and the conventional configuration (shown in FIG. 23) is represented by dashed double-dotted line A2. With regard to the in-plane uniformity of the deposition rate, the configuration of the present embodiment is represented by dashed dotted line B1, and the conventional configuration (shown in FIG. 23) is represented by dotted line B2.

When observing the in-plane distribution, in the present embodiment, the uniformity is higher as the distance between the target 31 and the wafer 10 is smaller, and gradually decreases as the distance increases. Further, when observing the deposition efficiency, the deposition efficiency is higher as the distance between the target 31 and the wafer 10 is smaller, and gradually decreases as the distance increases. Thus, in the configuration of the present embodiment, both the in-plane uniformity of the deposition rate and the deposition efficiency become better as the distance between the target 31 and the wafer 10 is smaller, and it is possible to achieve both of the in-plane uniformity of the deposition rate and the deposition efficiency.

On the other hand, in the conventional configuration, the in-plane uniformity of the deposition rate is very low when the distance between the target 31 and the wafer 10 is small, increases as the distance increases, and decreases again when the distance is larger than a certain distance. For this reason, it is required to increase the distance between the target 31 and the wafer 10 in order to ensure high in-plane uniformity, but if the distance increases, the deposition efficiency becomes considerably lower than that in the configuration of the present embodiment.

According to the embodiment described above, since a closed mesh-shaped horizontal magnetic field having no open end is formed, as described above, immediately below the target 31, a uniform plasma can be formed over the entire projection area of the wafer 10, and the in-plane uniformity of erosion is high. For this reason, the sputtering process can be performed in a state where the wafer 10 and the target 31 are made to be close to each other such that the distance between the wafer 10 and the target 31 is equal to or less than 30 mm. As a result, since fewer sputtered particles are deviated from the wafer 10 and adhere to the chamber shield member 44 or the holder shield member 45, it is possible to improve the deposition efficiency, and obtain a high deposition rate.

Further, there are irregularities in the erosion of the target 31 when seen microscopically, but some recess portions do not become deeper than other portions, and erosion proceeds uniformly throughout the surface. For this reason, it is possible to prolong the life of the target 31, and increase the utilization efficiency of the target 31.

Furthermore, according to the embodiment described above, the magnets 61 and 62 configured by assembling the magnet elements 63 are used, and a continuous horizontal magnetic field can be formed to be long. Accordingly, the electrons are accelerated to drift over a long distance. Thus, there are many opportunities of ionization, so that the plasma density becomes high. As a result, in the target 31, erosion proceeds promptly to emit many sputtered particles, thereby increasing the deposition rate.

Moreover, since the magnets 61 and 62 are configured by assembling the magnet elements 63, it is possible to easily adjust the magnetic force of one of the magnets 61 and 62. Further, since it is possible to adjust the number of the magnet elements 63 in the magnets 61 and 62, the number of the N-pole magnet elements 63 can be equal to the number of the S-pole magnet elements 63, and it is possible to achieve a balance between the N-pole magnetic flux and the S-pole magnetic flux. Accordingly, it is possible to suppress the bias of the horizontal magnetic field, and to suppress the formation of erosion and the occurrence of in-plane variation of the deposition rate.

Further, when viewed from the center O of the array of the inside magnet group 54, the number of the magnet elements 63 is set to be equal in the magnets 62a to 62d (the magnets 61b to 61e) whose centers are located on the same radius. Also, when viewed from the center O, the number of the magnet elements 63 is set to decrease as it goes toward the outside magnets. Accordingly, as will be apparent from embodiments to be described later, the in-plane uniformity of the deposition rate can be further improved.

In other words, in the N-pole magnets 61b, 61c, 61d and 61e placed at the four corners of the outermost periphery of the inside magnet group 54, on two sides among four sides, the S-pole magnets 62 where the magnetic flux converges are present adjacent to the two sides, but on the remaining two sides, the corresponding S-pole magnets 62 are absent. For this reason, between the magnets 61b, 61c, 61d and 61e and the adjacent magnets 62, the magnetic flux becomes large, and the horizontal magnetic field becomes strong. Therefore, as in the above-described embodiment, if the magnetic force is reduced by reducing the number of the magnet elements 63 constituting the magnets 61b, 61c, 61d and 61e, it is possible to achieve a balance of the horizontal magnetic field. In this case, the magnetic force of the magnets 61b, 61c, 61d and 61e may be reduced by using the magnet elements 63 having a small surface magnetic flux density without changing the number of the magnet elements 63.

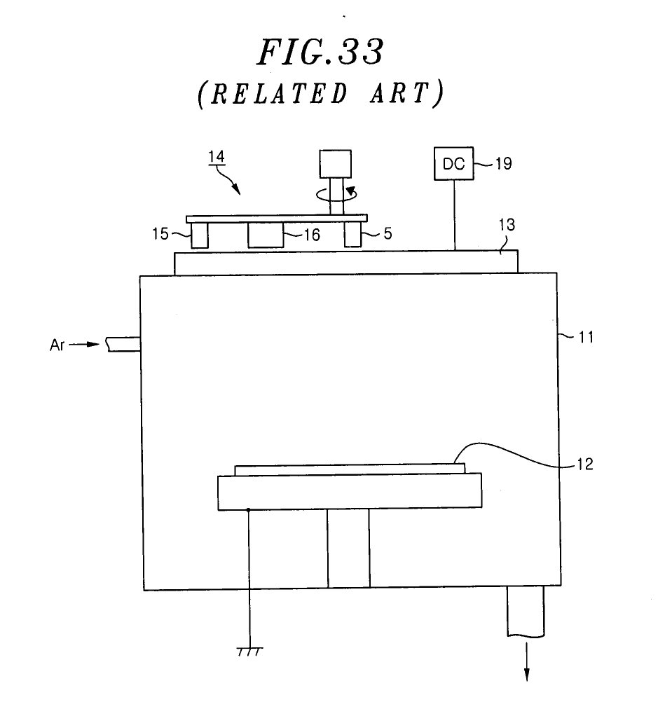

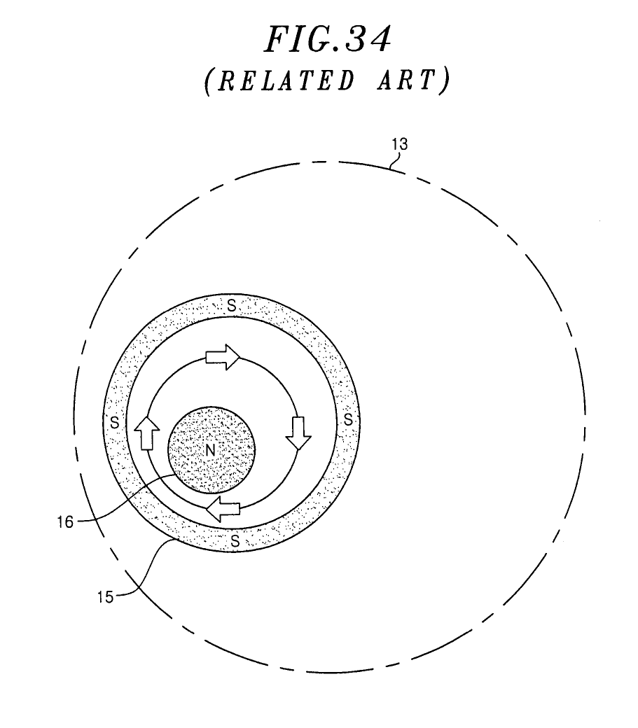

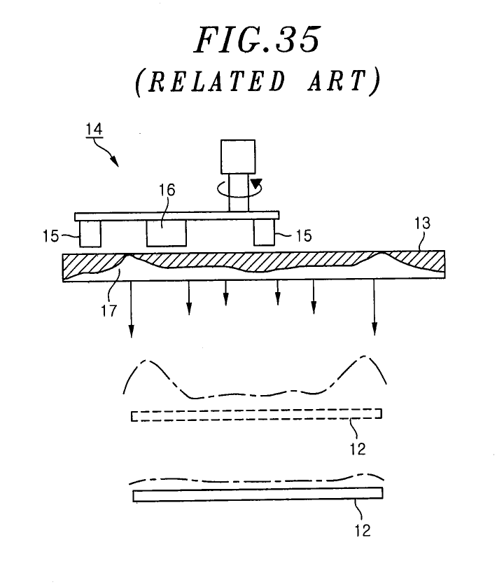

Thus, according to the configuration of the present embodiment, since it is possible to improve the deposition efficiency by about 400% (four times) compared to the conventional magnetron sputtering apparatus shown in FIG. 33, for example, even if applied power is about 4 kWh when the distance between the target 31 and the wafer 10 is 20 mm, it is possible to ensure the deposition rate of about 300 nm/min, and achieve the cost reduction by suppressing the power consumption. In addition, since the utilization efficiency also increases by about 80%, it is possible to achieve the cost reduction from this point of view.

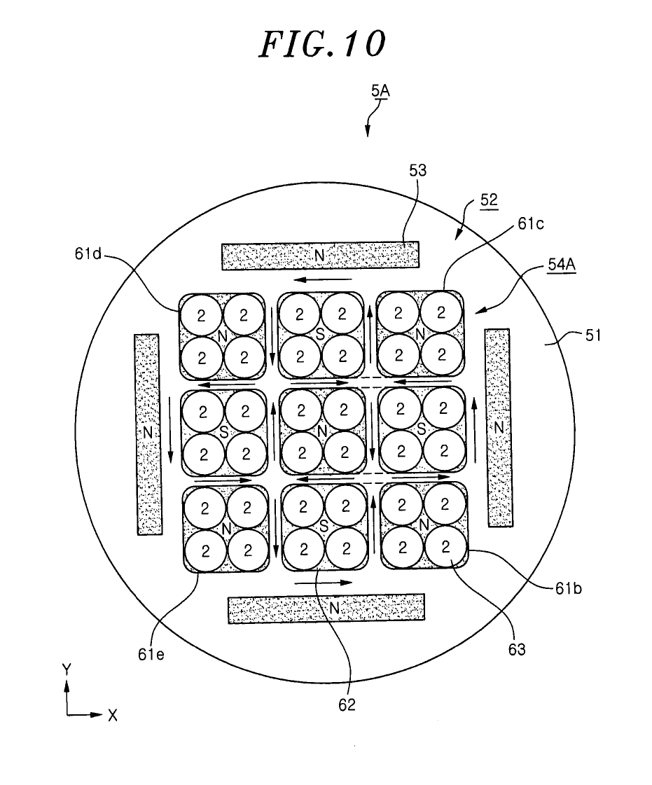

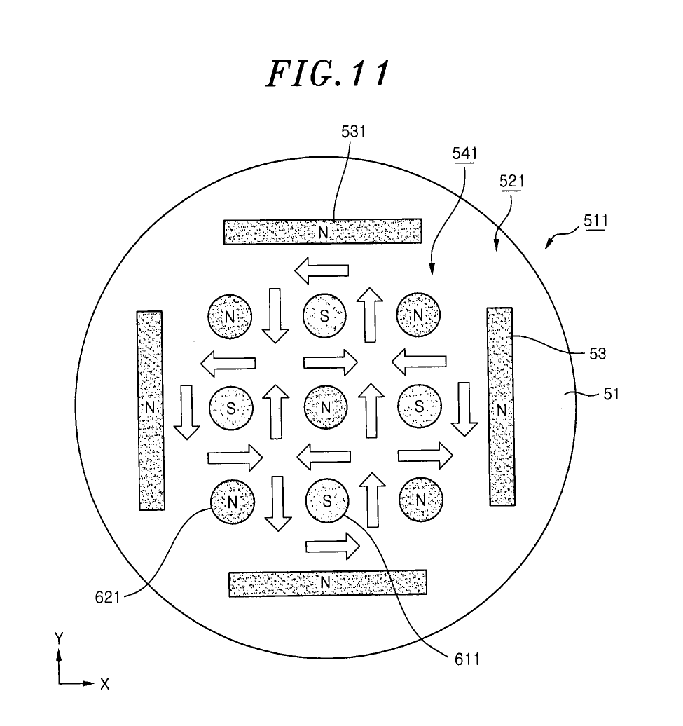

In the embodiment described above, the planar shape of the magnets 61 and 62 is not limited to a square shape, and may be a rectangular or circular shape. Further, the maximum number of the magnet elements 63 accommodated in one of the magnets 61 and 62 is not limited to eight. In addition, the number of the magnet elements 63 accommodated in the magnets 61 and 62 is not limited to the example shown in FIG. 2. For example, as shown in FIG. 10, each of the magnets 61 and 62 may be configured as a set of eight magnet elements 63. In this magnet array body 5A, by adjusting the surface magnetic flux density of the magnet elements 63, the magnetic force of an outside magnet located in the outermost periphery in an inside magnet group 54A may be adjusted to be smaller than the magnetic force of a magnet located inwardly of the corresponding outside magnet.

In the above-described example, since the magnet elements 63 are accommodated in the case body 64, there is an advantage that it is possible to facilitate the assembly of the magnet array body 5 by allowing the case body 64 to accommodate the predetermined magnet elements 63 in advance, but the magnet elements 63 do not necessarily need to be accommodated in the case body 64. In addition, as described above, the numbers of the return magnets 53 and the magnets 61 and 62 that are installed may be increased or decreased according to the size of the wafer 10. Also in this case, it is possible to obtain the same effect. Furthermore, although the outer edge of the target 31 is set on the inside of the magnet group 52 in the above-described example, the outer edge of the target 31 may be set on the outside of the magnet group 52.

Further, since the magnet array body 5 is rotated around the position eccentric from the center O of the base body 51, in the eccentric rotation, if a separation portion between of the return magnets 53 and the inside magnet group 54 is set to be in the area extending 50 mm outward from the outer edge of the wafer 10, it is possible to improve the uniformity of the deposition rate distribution. Similarly, if the sizes of the magnet array body 5 and the target 31 are set such that the outer edge of the target 31 is located in the separation portion between the return magnets 53 and the outer edge of the inside magnet group 54 in the eccentric rotation, it is possible to form the erosion on the entire surface of the target 31, and perform a uniform deposition process.

Subsequently, a magnet array body 511 in accordance with another example will be described. A magnet group 521 shown in FIG. 11 is an example in which an inside magnet group 541 is configured by arranging cylindrical point-shaped magnets 611 and 621 in a matrix of 3 columns×3 rows. The point-shaped magnets 611 and 621 are arranged to be equally spaced from each other such that the point-shaped magnets 611 and 621 adjacent to each other have opposite polarities. Also in this example, return magnets 531 are arranged in a line so as to surround the inside magnet group 541, and the directions in which the electrons drift are indicated by arrows in FIG. 11. As the point-shaped magnets 611 and 621, for example, magnets having a diameter of 20 to 30 mm and a thickness of 10 to 15 mm, and a surface magnetic flux density of 4 to 5 kG may be used. A distance between the centers of the point-shaped magnets 611 and 621 is set to, e.g., 60 mm.

Also in this example, similarly to the above-described embodiment, immediately below the target 31, a uniform plasma can be formed over the entire projection area of the wafer 10, and the in-plane uniformity of erosion is high. Thus, the sputtering process can be performed in a state where the wafer 10 and the target 31 are made to be close to each other. Accordingly, it is possible to ensure the in-plane uniformity of the high deposition rate while increasing the deposition efficiency, and also improve the utilization efficiency of the target 31. As the point-shaped magnets, in addition to magnets having a cylindrical shape, magnets having, e.g., an equilateral triangular prism shape having one side of 20 to 30 mm, or a cube shape having one side of 20 to 30 mm may be used.

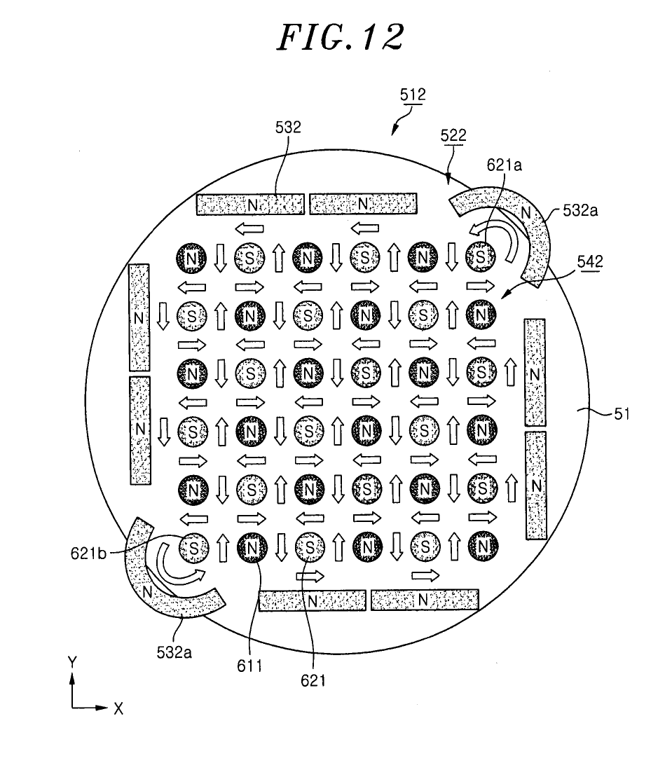

Further, the magnets may also be arranged in a matrix of n columns×m rows. A magnet group 522 of a magnet array body 512 shown in FIG. 12 is an example in which an inside magnet group 542 is configured by arranging the cylindrical point-shaped magnets 611 and 621 in a matrix of 6 columns×6 rows. Also in this example, the point-shaped magnets 611 and 621 are arranged to be equally spaced from each other vertically and horizontally such that the point-shaped magnets 611 and 621 adjacent to each other have opposite polarities. Arrows in FIG. 12 indicate the directions in which the electrons drift.

Further, on the outside of the inside magnet group 542, return magnets 532 of the same polarity are arranged in a line so as to surround the inside magnet group 542. In this example, since n and m are even numbers, the point-shaped magnets arranged in the outermost periphery of the inside magnet group 542 are configured such that the point-shaped magnets having different polarities are located at both ends. For this reason, in the vicinity of S-pole point-shaped magnets 621a and 621b at the corners of the inside magnet group 542, N-pole return magnets 532a are arranged in an arc shape to surround the point-shaped magnets 621a and 621b.

Therefore, in the magnet array body 512, even in the corners of the inside magnet group 542, electrons are prevented from jumping out of the cusp magnetic field, and it is possible to suppress the electron loss. Accordingly, similarly to the above-described embodiment, immediately below the target 31, a uniform plasma can be formed over the entire projection area of the wafer 10, and the in-plane uniformity of erosion becomes high. Thus, the sputtering process can be performed in a state where the wafer 10 and the target 31 are made to be close to each other. Accordingly, it is possible to ensure the in-plane uniformity of the high deposition rate while increasing the deposition efficiency, and also improve the utilization efficiency of the target 31.

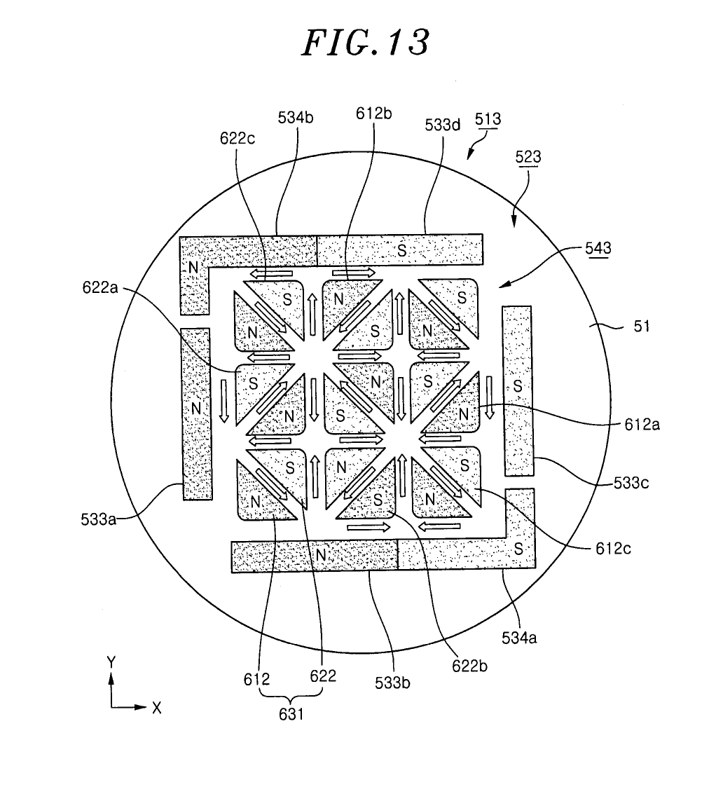

Further, the shape of the point-shaped magnets is not limited to a set of the magnet elements 63, or a cylindrical shape, and may be a triangular prism shape. A magnet group 523 of a magnet array body 513 shown in FIG. 13 is an example in which an inside magnet group 543 is configured by arranging triangular prism-shaped magnets 612 and 622. In this example, the planar shape of the magnets 612 and 622 is substantially an isosceles triangle shape, and the magnets 612 and 622 are arranged such that their hypotenuses are spaced from each other and face each other to form one unit 631. Also in this example, the magnets are arranged such that the magnets 612 and 622 adjacent to each other have opposite polarities.

Further, on the outside of the inside magnet group 543, return magnets 533 and 534 are arranged in a line so as to surround the inside magnet group 543. The return magnets 533 and 534 of this example are configured as four magnets 533a to 533d having a rectangular shape in a plane view and two magnets 534a and 534b having a substantially L shape in a plane view.

In this example, the return magnets 533a to 533d are respectively arranged on both sides in the transverse direction and the lateral direction of the inside magnet group 543, and set to have polarities different from those of magnets 622a, 622b, 612a and 612b placed in the center of the outermost periphery of the inside magnet group 543. Further, the return magnets 534a and 534b are provided corresponding to two opposite corners of the inside magnet group 543, in this example, at the upper left corner and the lower right corner. Thus, in the vicinity of the magnets 612c and 622c at the corners of the inside magnet group 543, the return magnets 534a and 534b of different polarities are arranged to surround the magnets 612c and 622c. Arrows in FIG. 13 indicate the directions in which the electrons drift.

Therefore, even in this magnet array body 513, since the return magnets 533 and 534 are arranged to cover most of the magnets 612 and 622 of the outermost periphery of the inside magnet group 543, electrons are prevented from jumping out of the cusp magnetic field, and it is possible to suppress the electron loss.

Therefore, similarly to the above-described embodiment, immediately below the target 31, a uniform plasma can be formed over the entire projection area of the wafer 10, and the in-plane uniformity of erosion becomes high. Thus, the sputtering process can be performed in a state where the wafer 10 and the target 31 are made to be close to each other. Accordingly, it is possible to ensure the in-plane uniformity of the high deposition rate while increasing the deposition efficiency, and also improve the utilization efficiency of the target 31.

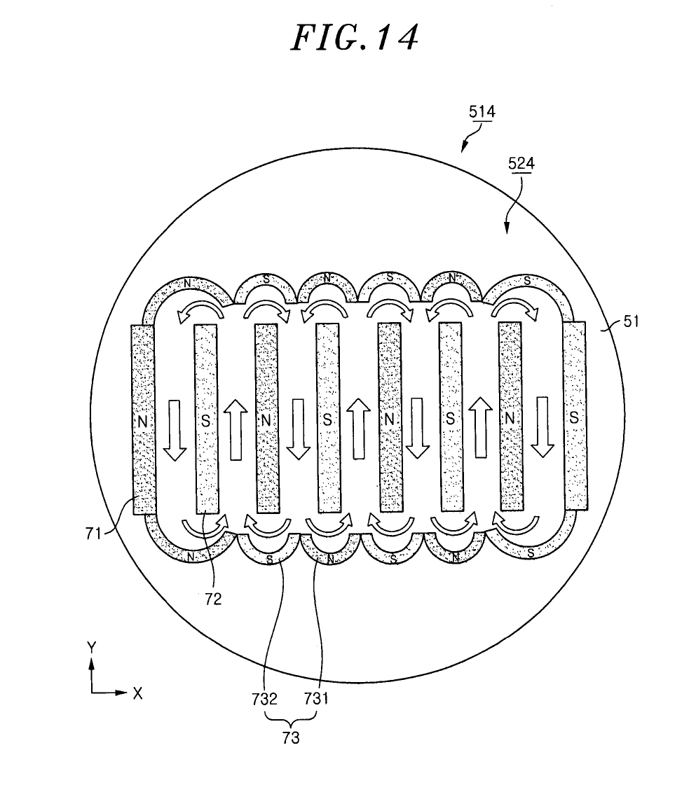

Further, in the present invention, as shown in FIG. 14, magnets 71 and 72 having a rectangular shape in a plane view may be arranged to be spaced from each other such that, for example, the length direction thereof is parallel to the transverse direction, and the magnets 71 and 72 adjacent to each other have different poles. Also, around the magnets 71 and 72, line-shaped magnets 73 (731 and 732) may be arranged in order to suppress electrons from jumping out.

In a magnet array body 514 of this example, the outermost magnets are set to have different poles in order to make the number of the N-pole magnets 71 equal to the number of S-pole magnets 72. Further, the line-shaped magnets 73 have, e.g., an arc shape in a plane view, and include N-pole magnets 731 and S-pole magnets 732. The line-shaped magnets 731 and 732 are arranged to extend in the lateral direction, and configured such that both ends (in the length direction) of the magnets 71 and 72 on both sides in the lateral direction are connected by the line-shaped magnets 731 and 732. Thus, the magnet group 524 is constituted by the magnets 71 and 72 and the line-shaped magnets 731 and 732. Arrows in FIG. 14 indicate the directions in which the electrons drift.

In this configuration, since the magnetic flux of the cusp magnetic field formed by the magnets 71 is coupled to the magnetic flux of the cusp magnetic field formed by the magnets 72, a horizontal magnetic field is formed between these magnets 71 and 72, and the electrons drift to cause the ionization. At both ends of the magnets 71 and 72, electrons naturally jump out of the magnetic field at the open end to cause electron loss, but since the line-shaped magnets 731 and 732 are arranged, the electrons are prevented from being released from the constraint of the cusp magnetic field and jumping out of the cusp magnetic field. Thus, it is possible to suppress the electron loss and achieve the uniformity and increase of electron density.

Therefore, similarly to the above-described embodiment, immediately below the target 31, a uniform plasma can be formed over the entire projection area of the wafer 10, and the in-plane uniformity of erosion becomes high. Thus, the sputtering process can be performed in a state where the wafer 10 and the target 31 are made to be close to each other. Accordingly, it is possible to ensure the in-plane uniformity of the high deposition rate while increasing the deposition efficiency, and also improve the utilization efficiency of the target 31.

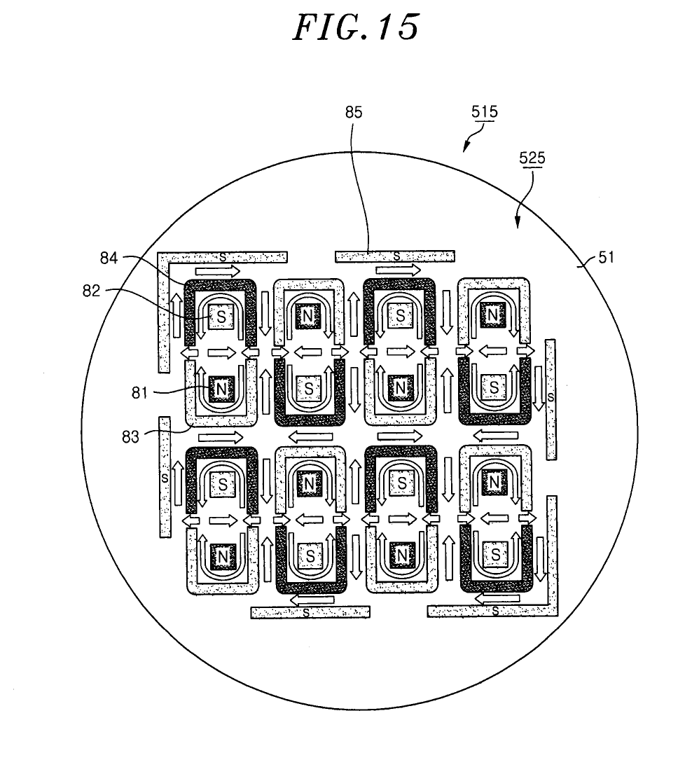

Further, in the present embodiment, a magnet group 525 of a magnet array body 515 may be configured as shown in FIG. 15. The magnet group 525 is configured by arranging magnets 81 and 82 having a square shape in a plane view in a matrix such that the magnets 81 and 82 adjacent to each other have different poles. Also, line-shaped magnets 83 and 84 having a substantially U shape and having polarities different from the magnets 81 and 82 are provided to surround the magnets 81 and 82. In addition, on the outside of the line-shaped magnets 83 and 84, line-shaped magnets 85 having a rectangular shape in a plane view are arranged.

In this configuration, since the magnetic flux of the cusp magnetic field formed by the magnets 81 and 82 is coupled to the magnetic flux of the cusp magnetic field formed by the line-shaped magnets 83, 84 and 85 to form a horizontal magnetic field network, the electrons drift in the directions shown by arrows in FIG. 15 along the horizontal magnetic field to cause the ionization. At this time, since the line-shaped magnets 83 to 85 are arranged, the electrons are prevented from being released from the constraint of the cusp magnetic field and jumping out of the cusp magnetic field. Thus, it is possible to suppress the electron loss and achieve the uniformity and increase of electron density. Therefore, similarly to the above-described embodiment, immediately below the target 31, a uniform plasma can be formed over the entire projection area of the wafer 10, and the in-plane uniformity of erosion becomes high. Thus, the sputtering process can be performed in a state where the wafer 10 and the target 31 are made to be close to each other. Accordingly, it is possible to ensure the in-plane uniformity of the high deposition rate while increasing the deposition efficiency, and also improve the utilization efficiency of the target 31.

Further, as a material of the target, in addition to tungsten, a conductor such as copper (Cu), aluminum (Al), titanium (Ti), titanium nitride (TiN), tantalum (Ta), tantalum nitride (TaNx), ruthenium (Ru), hafnium (Hf) and molybdenum (Mo), or an insulator such as silicon oxide and silicon nitride may be used. In this case, in case of using a target made of an insulator, a plasma is generated by applying a high frequency voltage to the target from the power supply unit. Also, by applying a high frequency voltage to a target made of a conductor, a plasma may be generated.

Further, the magnet array body may be rotated around a vertical axis with the center of the base body as the center of rotation by the rotating mechanism. Furthermore, the mounting part does not necessarily need to be used as an electrode, and there is no need to supply a high frequency power to the mounting part. In addition, in the magnet array body, a plurality of N poles and S poles constituting a magnet group may be arranged to be spaced to each other along the surface facing the target such that a plasma is generated over the entire projection area of the substrate to be processed based on the drift of electrons by the cusp magnetic field, and the arrangement of the magnets is not limited to the above example. For example, the shape or arrangement interval of the magnets constituting the inside magnet group may be varied in the surface of the base body.

Further, the magnet group may be configured such that a plasma is generated over the entire projection area of the substrate to be processed when rotating the magnet array body. Therefore, when eccentrically rotating the magnet array body, even if a portion of the outer edge of the substrate to be processed is positioned on the outside of the magnet group during the rotation, a plasma is generated over the entire projection area of the substrate to be processed when rotating the magnet array body.

Further, in the magnet group located inwardly of the return magnets, the sum of the strengths of the magnets corresponding to the N poles may be equal to the sum of the strengths of the magnets corresponding to the S poles. The strengths of the magnets may be adjusted by using, e.g., the number or size of the magnets or the like.

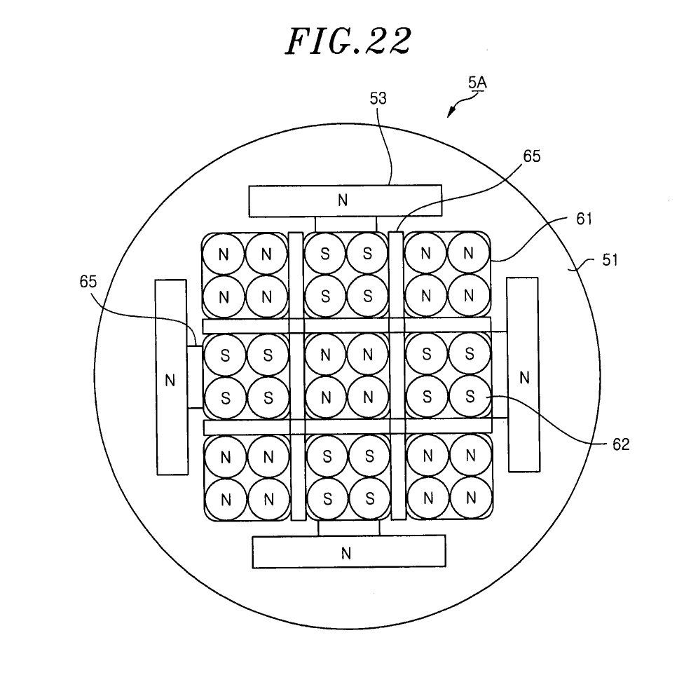

Next, there will be described a method of adjusting the strength of the horizontal magnetic field on the lower surface of the target by providing auxiliary magnets in the magnet array body described above. FIG. 22 shows an example in which auxiliary magnets 65 are provided in the magnet array body 5 shown in FIG. 10, which is a plan view of a magnet array body 5A when viewed from the target 31. The magnets 61, 62 and 53 of the magnet array body 5 shown in FIG. 10 are magnetized to have different magnetic poles at the side of the target 31 and the opposite side thereof as shown in FIG. 24. Further, the auxiliary magnets 65 are formed in a rectangular parallelepiped shape to fill the gap between the magnets 61 and 62, and the gap between the magnets 53 and 62. As shown in FIG. 23, the magnetic pole of the auxiliary magnets 65 is divided in a direction perpendicular to a longitudinal direction. N pole and S pole are magnetized on the opposite long sides, respectively.

With regard to a relationship between the magnetic pole of the magnet 61 (62, 53) and the magnetic pole of the auxiliary magnet 65 on the side of the target 31, the magnetic pole of the magnet 61 (62, 53) adjacent to one side of the auxiliary magnet 65 is set to have the same polarity as the magnetic pole of the one side of the auxiliary magnet 65. Thus, in the magnet array body 5A, on the side opposite to the side of the target 31 (the side of the base body 51), as shown in FIG. 24, the magnetic pole of the magnet 61 (62, 53) adjacent to one side of the auxiliary magnet 65 is set to have a polarity different from the magnetic pole of the one side of the auxiliary magnet 65.

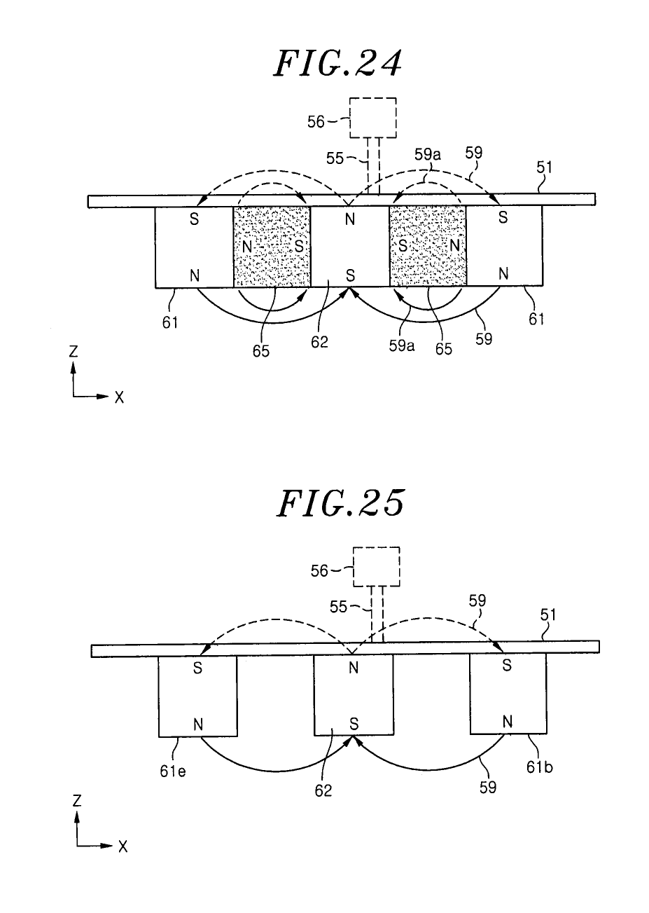

The state of the magnetic field of the magnet array body 5A including the auxiliary magnets 65 is illustrated in FIG. 24 using a portion where the auxiliary magnets 65 are provided between the magnets 61 and 62 as an example. Further, the state of the magnetic field in the magnet array body 5 without using the auxiliary magnets 65 is illustrated in FIG. 25 for comparison.

On the side of the base body 51, since the direction of magnetic force lines generated by the magnets 61 and 62 is opposite to the direction of magnetic force lines generated by the auxiliary magnets 65, the horizontal magnetic field formed by the magnets 61 and 62 is canceled and weakened or lost by the horizontal magnetic field formed by the auxiliary magnets 65.

On the other hand, on the side of the target 31, since the direction of magnetic force lines generated by the magnets 61 and 62 is the same as the direction of magnetic force lines generated by the auxiliary magnets 65, the horizontal magnetic field formed by the magnets 61 and 62 is overlapped with the horizontal magnetic field formed by the auxiliary magnets 65, so that the horizontal magnetic field is strengthened.

When using magnets having the same magnetic force as the magnets 61 and 62 as the auxiliary magnets 65, the strength of the magnetic field generated on the side of the target 31 in the magnet array body 5A is doubled, whereas the magnetic field generated on the side of the base body 51 is substantially zero. The strength of the magnetic field generated on the side of the target 31 is adjustable depending on the magnitude of the magnetic force of the auxiliary magnets 65, and can be adjusted by the height or width of the auxiliary magnets 65 and the surface magnetic flux density.

Typically, the size of the rectangular parallelepiped of the auxiliary magnet 65 is set to have a width of 20 to 30 mm, which is the same as the diameter or width of the magnets 61 and 62, a length of 30 mm, which is a distance between the magnets 61 and 62, and a height which is 1/3, 1/2, 1/1 of the height of the magnets 61 and 62. Further, the surface magnetic flux density of the auxiliary magnets 65 is 4 to 5 kGauss. If the surface magnetic flux density of the auxiliary magnets 65 is substantially the same as the surface magnetic flux density of the magnets 61 and 62, the magnetic field generated in the target 31 is increased by approximately a ratio of the height of the auxiliary magnets to the height of the magnets 61 and 62. Thus, as described above, when the height of the auxiliary magnets 65 is set to 1/3, 1/2, 1/1 of the height of the magnets 61 and 62, the strength of the magnetic field generated in the target 31 is increased by about 30%, about 50%, about 100% respectively. The same is true for the amount of cancellation of the magnetic field at the side of the base body 51. Also in a case where the height of the auxiliary magnets 65 is set to be equal to the height of the magnets 61 and 62, and the width of the auxiliary magnets 65 is set to 1/3, 1/2, 1/1 of the width of the magnets 61 and 62, the same effect can be obtained.

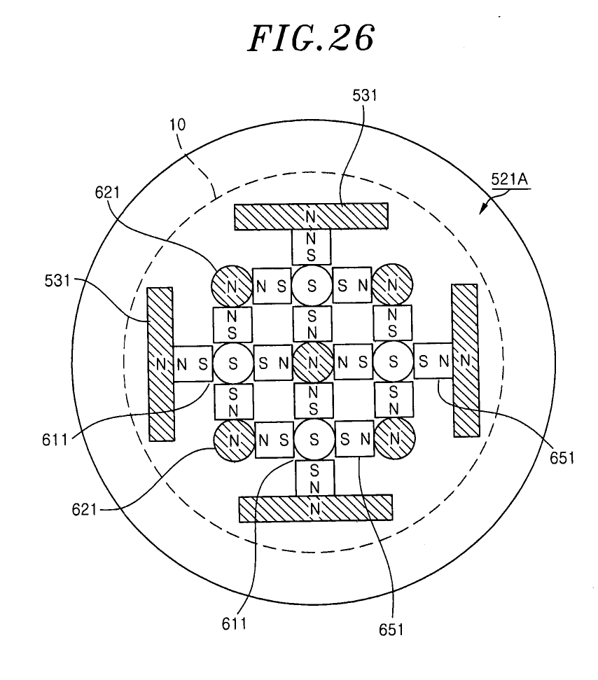

The auxiliary magnets 65 are not limited to those provided in the magnet array body 5 shown in FIG. 10. FIG. 26 illustrates an example in which auxiliary magnets 651 are provided in the magnet array body 511 shown in FIG. 11. A relationship between the magnet poles in the auxiliary magnets 651 and the positions of the magnets 611, 621 and 531 is the same as in the example of FIG. 22. The same is true for the effect.

Further, based on the knowledge obtained from the embodiment described above, the present inventors have studied on a method of dramatically reducing running costs while maintaining the in-plane uniformity of the sputter deposition by using the magnetron sputtering apparatus of the present embodiment. In order to reduce the running costs, it is considered that it is important to further increase the deposition efficiency and the utilization efficiency of the target 31 and also improve the deposition rate.

In order to increase the deposition efficiency, it is effective to shorten the distance TS between the surface of the wafer 10 and the lower surface of the target 31. Assuming that the power applied to the target 31 is constant, the amount of deposition is significantly improved as the distance TS is shorter. However, if the distance TS is excessively reduced, it is impossible to obtain sufficient in-plane uniformity. Accordingly, it is necessary to know a range of the distance TS in which the sufficient in-plane uniformity can be obtained while maintaining a large amount of deposition.

On the other hand, in order to improve the utilization efficiency of the target 31, it is effective to make uniform the erosion occurring in the target 31. This is because the maximum target utilization efficiency is obtained if the shape of the erosion is uniform. Therefore, if the distance TS is set to an appropriate value, it is possible to obtain the sufficient deposition efficiency and also obtain the deposition distribution needed under uniform erosion.

Thus, focusing on the uniformity of the deposition, in the sputtering using the magnetron sputtering apparatus according to the above-described embodiment, a simulation on the relationship between the target diameter and the distance TS was conducted. For erosion, it was assumed that the particles are emitted isotropically from the target, the particles constituting the target is sputtered and reduced in proportion to the square of the distance TS, and uniform erosion is formed.

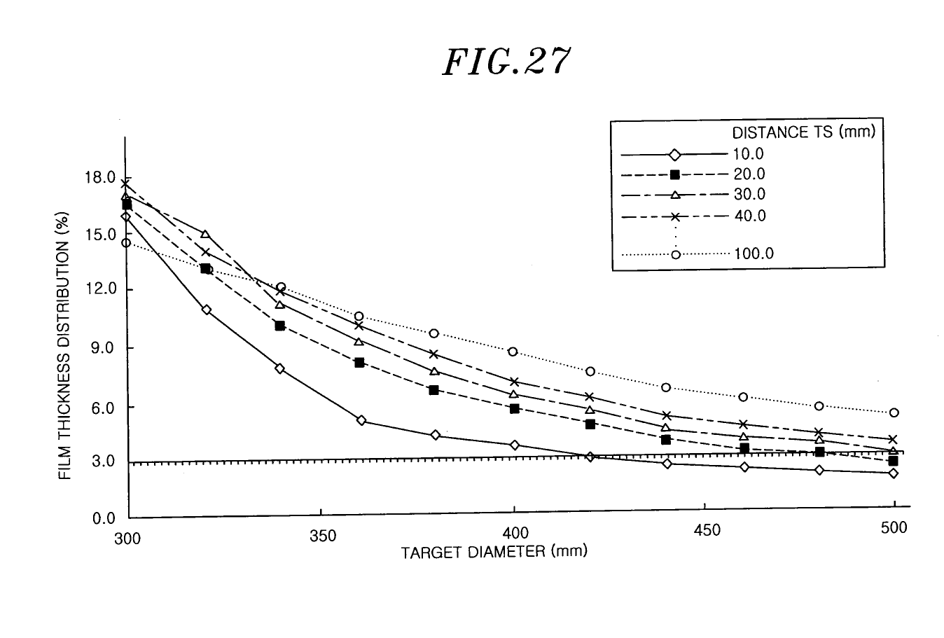

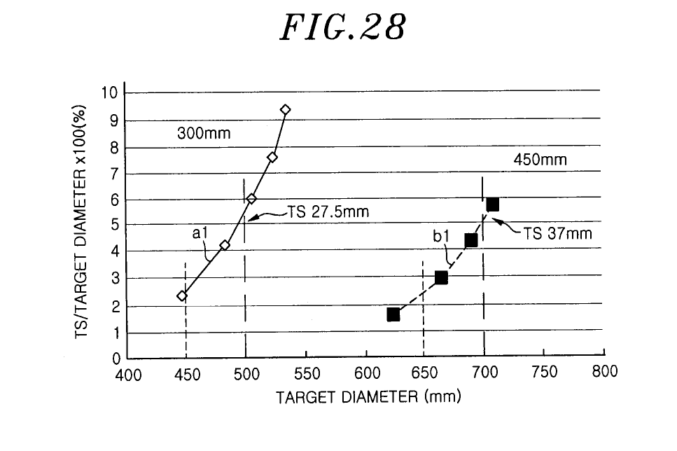

FIGS. 27 and 28 show the results of the simulation. In the simulation, the evaluation of in-plane uniformity of the film thickness of the wafer 10 was performed using a film thickness distribution calculated by the following equation:

Film thickness distribution (%)={standard deviation (1σ)/average value of film thickness at each point}×100

Specifically, in the case of the wafer having a diameter of 300 mm, the film thickness distribution was simulated while the target diameter is increased by 20 mm from 300 mm to 500 mm, and the distance TS is increased by 10 mm from 10.0 mm to 100.0 mm for each target diameter. FIG. 27 is a graph which shows a relationship between the target diameter and the film thickness distribution using the distance TS as a parameter, wherein the target diameter is plotted on a horizontal axis and the film thickness distribution is plotted on a vertical axis. In order to avoid the complexity of illustration due to the overlap of diagrams, a diagram for the distance TS of 50 to 90 mm is not illustrated. In FIG. 27, the diagram for the distance TS of 50 to 90 mm is located between a case of the distance TS of 40 mm and a case of the distance TS of 100 mm. It can be seen from this graph that the film thickness distribution is improved as the target diameter is larger and the distance TS is smaller.

A graph a1 on the left side (solid line) of FIG. 28 is a graph obtained by re-plotting an intersection between the line of the film thickness distribution of 3% and each curve in the graph of FIG. 27. In FIG. 28, a horizontal axis represents the target diameter, and a vertical axis represents a percentage of the distance TS to the target diameter. A graph b1 on the right side (dashed line) of FIG. 28 is a graph obtained by performing a simulation similar to the above simulation on the wafer having a diameter of 450 mm and plotting the target diameter and a percentage of the distance TS to the target diameter respectively on a horizontal axis and a vertical axis in the case of the film thickness distribution of 3%.

Since the target diameter used in the field of mass production of the wafer having a diameter of 300 mm is generally 450 to 500 mm, the target for the wafer having a diameter of 450 mm is assumed to have a shape similar to the case of the wafer having a diameter of 300 mm, and the target diameter was set to 500 mm to 700 mm. From the solid line in FIG. 28, it can be seen that the distance TS when the film thickness distribution of 3% is formed on the wafer having a diameter of 300 mm is about 2.4% (=about 11 mm) of the target diameter in the case of the target diameter of 450 mm, and about 5.5% (=about 27.5 mm) of the target diameter in the case of the target diameter of 500 mm. From the dashed line in FIG. 28, it can be seen that the distance TS when the film thickness distribution of 3% is formed on the wafer having a diameter of 450 mm is about 2.5% (=about 16 mm) of the target diameter in the case of the target diameter of 650 mm, and about 5.3% (=about 37 mm) of the target diameter in the case of the target diameter of 700 mm.

Therefore, a ratio (percentage) of the distance TS (mm) to the target diameter (mm) when the film thickness distribution is equal to or less than 3% corresponds to an area below the graph a1 of FIG. 28 in the case of the wafer having a diameter of 300 mm, and corresponds to an area below the graph b1 of FIG. 28 in the case of the wafer having a diameter of 450 mm. If the ratio ((TS/R)×100%) is Y % and the target diameter is R (mm), approximate expressions of Y and R with respect to the graphs a1 and b1 are represented respectively by Expressions (1) and (2):

Wafer of 300 mm diameter

Y=0.0006151R²−0.5235R+113.4 (1)

Wafer of 450 mm diameter

Y=0.0003827R²−0.4597R+139.5 (2)

Therefore, if it is assumed that a process in which the film thickness distribution is equal to or less than 3% is a preferable process, in order to perform the preferable process, a relationship of Expression (1′) should be satisfied in the wafer having a diameter of 300 mm and a relationship of Expression (2′) should be satisfied in the wafer having a diameter of 450 mm:

Y≦0.0006151R²−0.5235R+113.4 (1′)

Y≦0.0003827R²−0.4597R+139.5 (2′)

Expressions (1′) and (2′) are approximate expressions and there are some errors. Further, even if the film thickness distribution defined in the above Expressions for a thin film sputtered on the wafer is slightly more than 3%, it can be said that it does not affect the evaluation that the film thickness distribution is good. Further, the graph of FIG. 28 (approximate expression (1) described above) is obtained based on the results of FIG. 27 by the simulation when the distance TS was digitally changed. Putting these together, it is difficult to say that an upper limit (boundary value) of the distance TS at which the effect of good film thickness distribution is obtained is optimally determined only by approximate expressions (1) and (2) described above. For example, when the wafer diameter is 300 mm and the target diameter is 500 mm, the upper limit of the distance TS making the film thickness distribution equal to or less than 3% is 27.125 mm when calculated by Expression (1). However, even if the distance TS is 30 mm, the film thickness distribution is slightly more than 3% from the graph of FIG. 27, but the evaluation that the film thickness distribution is good can be made. Further, when the wafer diameter is 300 mm and the target diameter is 450 mm, the upper limit of the distance TS making the film thickness distribution equal to or less than 3% is 10.722 mm when calculated by Expression (1). However, even if the distance TS is 12 mm, the film thickness distribution is slightly more than 3% from the graph of FIG. 27, but since it is slightly in excess, the effect is substantially equal to the effect that the film thickness distribution is 3%.

Further, when the wafer diameter is 450 mm and the target diameter is 700 mm, the upper limit of the distance TS making the film thickness distribution equal to or less than 3% is 36.631 mm when calculated by Expression (2). However, even if the distance TS is 40 mm, the film thickness distribution is slightly more than 3%, but it can be said that the film thickness distribution is good. Therefore, by using Expressions (1) and (2) described as an indicator for determining the upper limit of the distance TS making the film thickness distribution good, and giving a slight margin to the obtained value of the distance TS, the upper limit (boundary value) was allowed to be determined appropriately. Although the effect of the present invention is difficult to be obtained if the margin is too large, in order to clarify the invention in the specification, the margin was determined in a range which does not cause doubt that an object of the present invention can be obtained. Specifically, in the case of the wafer having a diameter of 300 mm, the upper limit was determined as a 10% increase in the value of the distance TS obtained by Expression (1). In the case of the wafer having a diameter of 450 mm, the upper limit was determined as a 10% increase in the value of the distance TS obtained by Expression (2).

When this meaning is represented as expressions, in the case of the wafer having a diameter of 300 mm, the appropriate value of the distance TS (mm) is calculated by the following expression:

Y=(TS′/R)×100(%)=0.0006151R²−0.5235R+113.4

TS≦1.1TS′ (3)

TS′ represents an appropriate separation distance between the wafer and the target calculated by Expression (1), and TS represents an upper limit of the appropriate separation distance calculated by giving a margin of 10% to TS′.

Further, in the case of the wafer having a diameter of 450 mm, the appropriate value of the distance TS (mm) is calculated by the following expression:

Y=(TS′/R)×100(%)=0.0003827R²−0.4597R+139.5

TS≦1.1TS′ (4)

Although not specified for a lower limit of the distance TS, since the effect of the present invention can be obtained even if it is slightly smaller than the upper limit, it is considered that there is no significance of precisely defining the lower limit. Putting the mechanism of sputtering and the like together, the present inventors have inferred that if the distance TS is greater than 5 mm, for example, the same effect as the value of the distance TS in each plot shown in FIG. 28 is obtained.

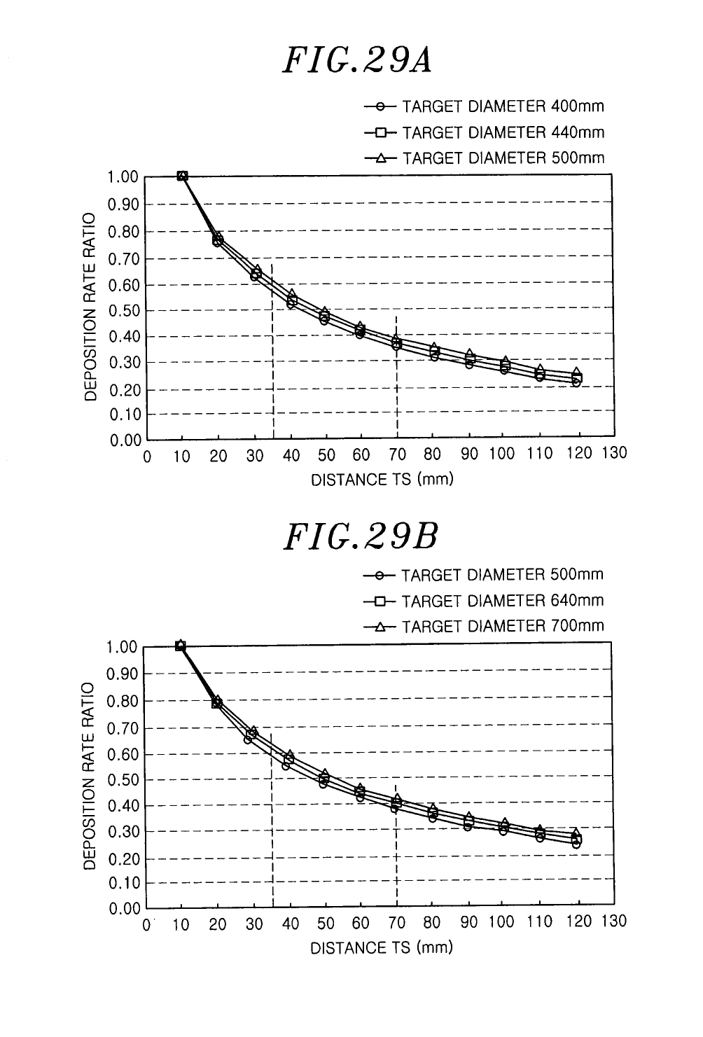

On the other hand, from the viewpoint of improving the deposition rate, a simulation was also conducted on the relationship between the deposition rate and the distance TS. Specifically, in the cases where the wafer diameter is 300 mm and 450 mm, the dependency of the deposition rate on the distance TS was simulated by using three types of targets having different diameters. FIGS. 29A and 29B show the obtained results, wherein FIG. 29A represents the simulation results in the case of the wafer having a diameter of 300 mm, and FIG. 29B represents the simulation results in the case of the wafer having a diameter of 450 mm. In the case of the wafer having a diameter of 300 mm, conventionally, the distance TS is set to 70 mm in many cases, and thus, the evaluation is conducted based on the deposition rate when the distance TS is 70 mm. Further, in the case of the wafer having a diameter of 450 mm, it is simply considered as a similar shape, and the evaluation is conducted based on the deposition rate when the distance TS is 105 mm that is 1.5 times. From the graph of FIG. 29A, the distance TS when the deposition rate of 1.5 times the deposition rate in the case of TS=70 mm is obtained is calculated to be about 35 mm. Similarly, from the graph of FIG. 29B, in the case of the wafer having a diameter of 450 mm, the distance TS when the deposition rate of 1.5 times the deposition rate in the case of TS=105 mm is obtained is calculated to be about 55 mm. Thus, the distance TS when the deposition rate of 1.5 times or more with respect to the evaluation criteria is obtained is equal to or less than 35 mm in the case of the wafer having a diameter of 300 mm, and equal to or less than 55 mm in the case of the wafer having a diameter of 450 mm. When the distance TS is converted into the ratio (TS/target diameter), in the case of the wafer having a diameter of 300 mm, TS/target diameter is equal to or less than about 8% when the target diameter is 450 mm. In the case of the wafer having a diameter of 450 mm, TS/target diameter is equal to or less than about 8% when the target diameter is 700 mm.

These results mean that the deposition rate of 1.5 times is obtained as compared to the deposition rate of the evaluation criteria in the areas below the graphs a1 and b1 of FIG. 28. Therefore, if the relationship between the ratio Y (TS/target diameter R) and the target diameter R satisfies Expressions (1′) and (2′) described above, the deposition can be performed while achieving both the film thickness distribution of 3% or less and the deposition rate of 1.5 times or more.

Further, low resistance wiring (including conductive paths and electrodes) can be deposited at high speed by adjusting the process pressure by using the magnetron sputtering apparatus of the present embodiment. To describe this method, the magnet group is adjusted such that the strength of the magnetic field on the surface of the target is equal to or greater than, e.g., 100 G. Then, while the process pressure is set to be equal to or greater than 13.3 Pa (100 mTorr), a DC power is applied to the target 31 from the power supply unit 33 (see FIG. 1), and a discharge power density obtained by dividing its power value by the area of the target is set to a value equal to or greater than, e.g., 3 W/cm². Further, the voltage applied to the target 31 is set to be equal to or less than, e.g., 300 V, and the high frequency power applied to the mounting part 4 from the high frequency power supply unit 41 is set to, e.g., 500 W to 2000 W.

When sputtering is performed under these conditions, as described in detail in the discussion of experimental examples to be described below, the distance between the target and the substrate (to be processed) is narrow and the discharge is performed over the entire surface of the substrate by the magnets as described above. Accordingly, a high ion density can be maintained even in the vicinity of the substrate, and a W film can be deposited at a high deposition rate under high pressure conditions of 13.3 Pa or more. Thus, it is possible to achieve both of high speed and high efficiency sputtering and the deposited film of low resistance.

In the above, the magnetron sputtering apparatus of the present invention can be applied to a sputtering process of a substrate to be processed, which is made of glass for solar cells or liquid crystal displays, plastic or the like, in addition to a semiconductor wafer.

### EXAMPLES

### Example 1

In the magnetron sputtering apparatus including the magnet array body 511 of FIG. 11, a deposition process was carried out under the processing conditions described above, and the evaluation of the relationship between the current density and the DC voltage applied to the target electrode 3 was conducted. At this time, the distance between the target 31 and the wafer 10 was set to 30 mm. Further, a configuration (Comparative Example 1) in which the return magnets 531 are not provided in the magnet array body 511, a configuration (Comparative Example 2) using the conventional magnetron sputtering apparatus shown in FIG. 23, and a configuration (Comparative Example 3) in which the discharge is performed by applying a DC voltage without using magnets were also evaluated in the same manner.

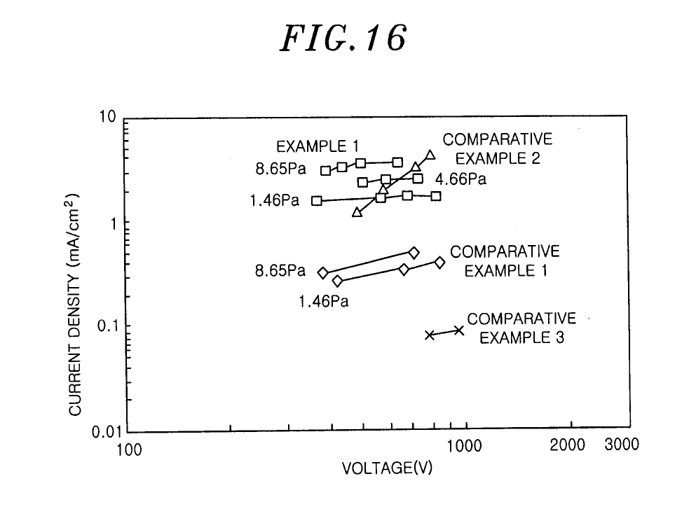

FIG. 16 shows the results. In FIG. 16, the horizontal axis represents the DC voltage applied to the target electrode 3, and the vertical axis represents the current density between the wafer 10 and the target 31. Further, □ was plotted for Example 1, ⋄ was plotted for Comparative Example 1, Δ was plotted for Comparative Example 2, and X was plotted for Comparative Example 3.

As a result, the current density was 2 to 4 mA/cm² in Example 1, and 0.2 to 0.5 mA/cm² in Comparative Example 1. It was observed that the current density was considerably increased by providing the return magnets. Accordingly, it is understood that the plasma density can be increased and electron loss can be suppressed by the arrangement of the return magnets. Further, it was observed that the high current density can be ensured even if the applied voltage is small in Example 1 as compared with Comparative Example 2. Further, it was confirmed that the deposition rate of about 100 nm/min was obtained by the application of electric power of 400 W.

### Example 2

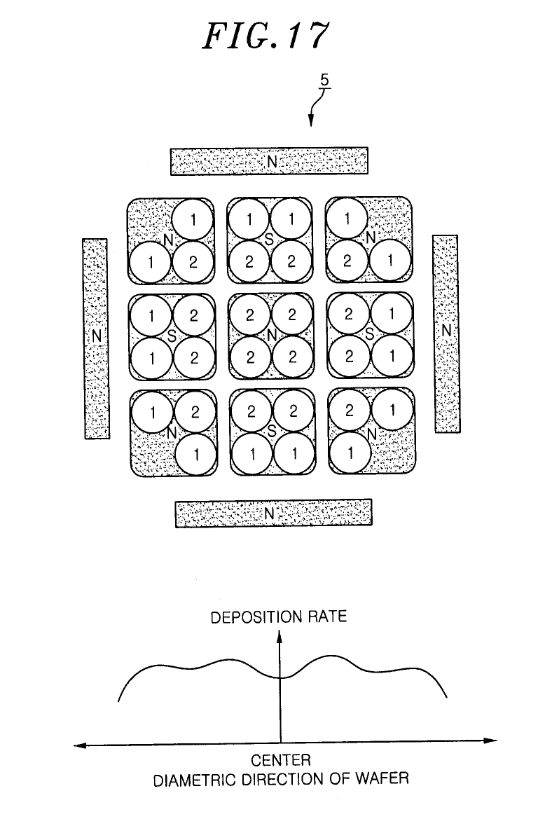

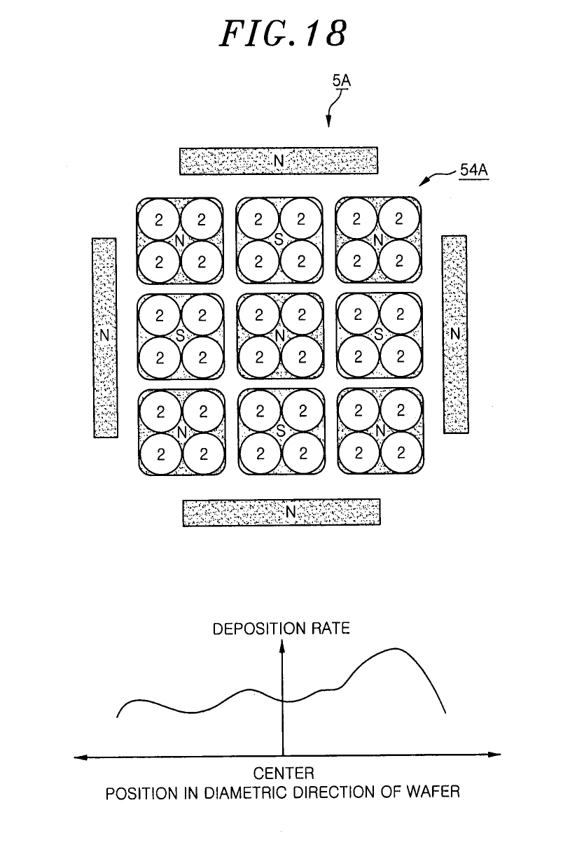

In the magnetron sputtering apparatus including the magnet array body 5 of FIG. 2, a deposition process was carried out under the processing conditions described above without rotating the magnet array body 5, and the deposition rate distribution in the radial direction of the wafer was obtained. Also in the case where the magnet array body 5A of FIG. 10 is provided instead of the magnet array body 5 of FIG. 2, the deposition rate was measured in the same manner. The results for the configuration in which the magnet array body 5 is provided are shown in FIG. 17, and the results for the configuration in which the magnet array body 5A is provided are shown in FIG. 18.

Here, a difference between the magnet array body 5 and the magnet array body 5A is only the number of the magnet elements 63 constituting the magnets 61 and 62. However, by adjusting the number of the magnet elements 63, it was observed that the deposition rate distribution in the radial direction of the wafer 10 was changed. Thus, it is understood that by adjusting the number of the magnet elements 63, the magnetic force of one of the magnets 61 and 62 is adjusted, thereby controlling the in-plane uniformity of the deposition rate.

Further, the magnet array body 5 is configured such that the number of N poles is equal to the number of S poles, the number of the magnet elements 63 is equal in the magnets on the same radius from the center O of the array, and the number of the magnet elements 63 decreases as it goes away from the center O of the array. However, from the results of FIG. 17, it was found that by adopting the configuration of the magnet array body 5, the deposition rate was uniform in the radial direction of the wafer 10, and the in-plane uniformity was improved.

Furthermore, it was found from the results of FIG. 18 that in the case where the number of the magnet elements 63 is equal in all of the magnets 61 and 62, the deposition rate on one side of the peripheral portion in the radial direction of the wafer 10 was increased. It is inferred that this is because in the magnets 61a to 61d at the four corners of the inside magnet group 54A, as described above, the magnetic flux between the magnets 61a to 61d and the adjacent magnets becomes larger, and the horizontal magnetic field of that portion becomes stronger than the inside region in which the magnetic flux is balanced. However, the deposition rate distribution can be more uniform by adjusting the distance between the target 31 and the wafer 10, or the distance between the return magnets and the outside magnets in the outermost periphery of the inside magnet group 54A, or rotating the magnet array body 5A around a vertical axis.

### Example 3

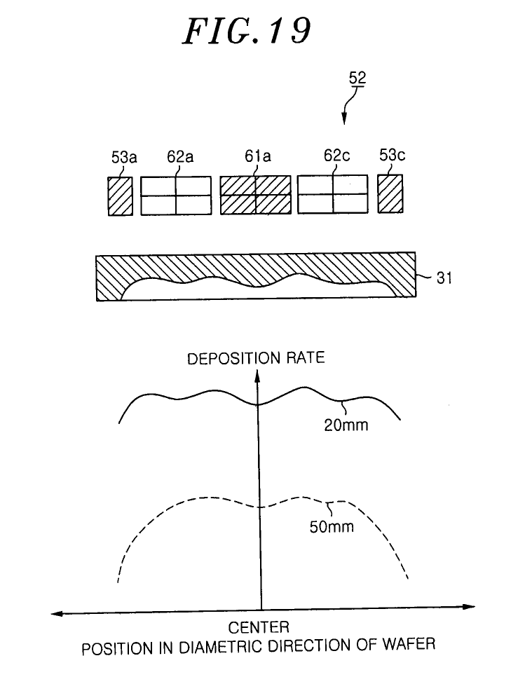

In the magnetron sputtering apparatus including the magnet array body 5 of FIG. 2, the distance between the target 31 and the wafer 10 was set to 20 mm, and a deposition process was carried out under the processing conditions described above without rotating the magnet array body 5 to obtain the deposition rate distribution in the radial direction of the wafer. Also in the case where the distance between the target 31 and the wafer 10 was set to 50 mm, the deposition rate was measured in the same manner. The results are shown in FIG. 19 along with the array of the magnet group 52 of the magnet array body 5 and the state of the erosion of the target 31. Further, in Example 3, the target 31 larger than the magnet group 52 of the magnet array body 5 was used.

Thus, it was observed that when the distance between the target 31 and the wafer 10 is 20 mm, the in-plane uniformity of the deposition rate is higher than that when the distance is 50 mm. Further, it was confirmed that in the case of the distance of 20 mm, the deposition rate when a DC voltage (power of about 4 kWh) was applied to the target electrode 3 was 300 nm/min, and the average deposition rate also increases compared to the case of the distance of 50 mm. Furthermore, it was observed that although the deposition rate distribution in the radial direction of the wafer 10 has a slightly uneven shape, irregularities were formed at regular intervals in the radial direction of the wafer 10. It is understood that the deposition rate reflects the erosion shape since the erosion is formed in the intermediate portion between magnets having poles different from each other.

Further, it was observed that when the distance was 50 mm, the deposition rate in the outer periphery of the wafer was reduced abruptly. It is inferred that this is because the particles sputtered from the outer periphery of the target 31 scattered to the outside, and less particles reach the wafer 10, thereby reducing the deposition efficiency. In addition, in the center of the wafer 10, the unevenness of the deposition rate was weakened, and it is considered that this is because the distance from the target is large, the particles diffuse, and it is less susceptible to erosion.

From Example 3, it was confirmed that in the magnet array body 5, when the target 31 and the wafer 10 were brought close to each other, the uniformity of the deposition rate can be ensured and it is possible to achieve both the deposition efficiency and the uniformity of the deposition rate.

### Example 4

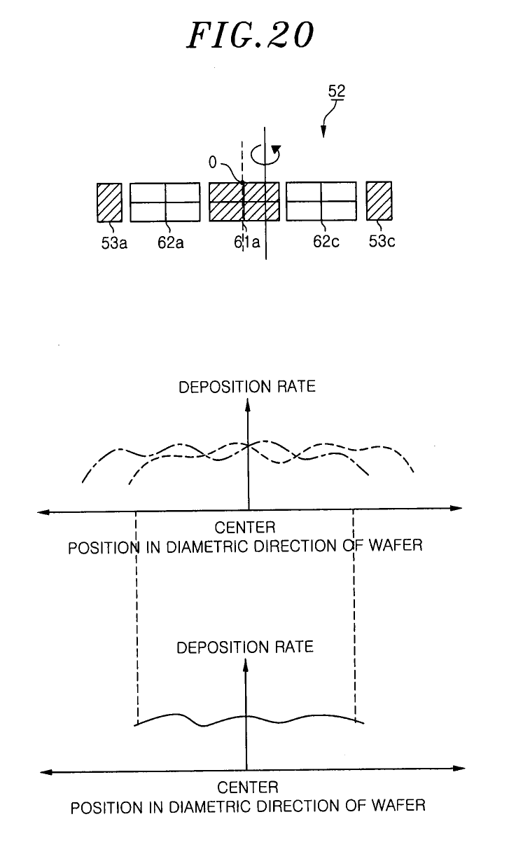

In the magnetron sputtering apparatus including the magnet array body 5 of FIG. 2, the distance between the target 31 and the wafer 10 was set to 20 mm, and a deposition process was carried out under the processing conditions described above while rotating the magnet array body 5 to obtain the deposition rate distribution in the radial direction of the wafer. In this case, the magnet array body 5 was rotated around a vertical axis with the position 25 mm eccentric from the center of the base body 51 as the center of rotation. The results are shown by a solid line in FIG. 20. Also, in FIG. 20, the data when the sputtering process was performed while the magnet array body 5 was stationary at a certain position without rotation is represented by a dashed dotted line, and the data when the sputtering process was performed while the magnet array body 5 was stationary at a position after 1/4 revolution from the position is represented by a dotted line.

From these results, it was observed that in the deposition rate distribution when the magnet array body 5 was stationary, the irregularities were formed periodically in the radial direction of the wafer 10, but by rotating the magnet array body 5 eccentrically from the center of the base body 51, the irregularities were offset, thereby promoting the uniformity of the deposition rate distribution.

### Example 5

In the magnetron sputtering apparatus including the magnet array body 5 of FIG. 2, the distance between the target 31 and the wafer 10 was set to 20 mm, and a deposition process was carried out under the processing conditions described above while rotating the magnet array body 5 to obtain the deposition rate distribution in the radial direction of the wafer. The amount of eccentricity of the magnet array body 5 was the same as that of Example 4. In this case, the evaluation was conducted for a case P1 where the separation distance L3 between the return magnets 53 and the outside magnets in the outermost periphery of the inside magnet group 54 was set to 5 mm, and a case P2 where the separation distance L3 was set to 30 mm.

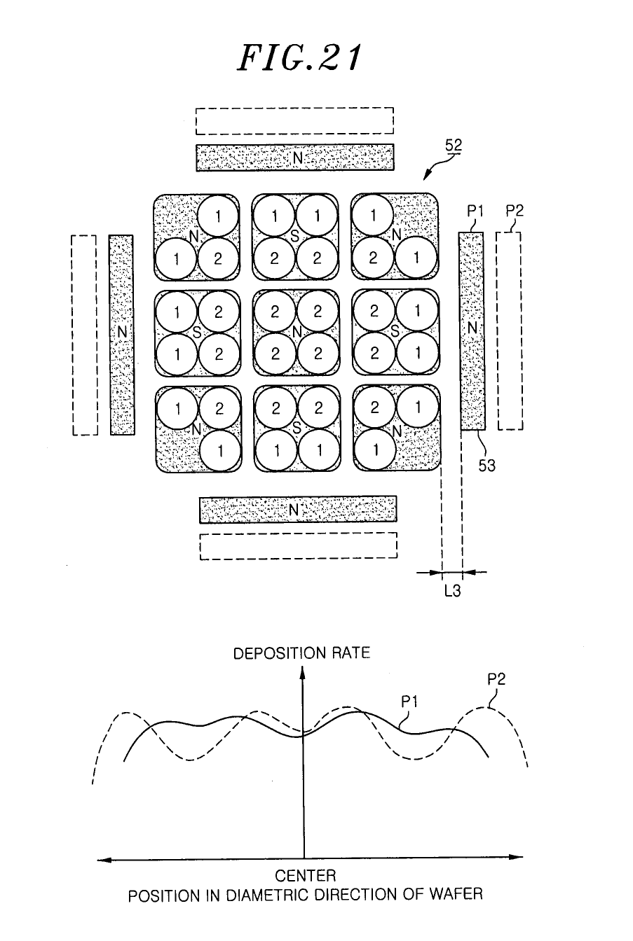

The results for the case P1 are shown by a solid line and the results for the case P2 are shown by a dotted line in FIG. 21. Thus, it was observed that the deposition rate distribution was changed by changing the separation distance L3, and it is understood that the erosion position can be controlled by adjusting the positions of the magnets. Therefore, it was recognized that by optimizing the size and arrangement of the magnets and the distance between the magnets, it is possible to form a desired erosion and optimize the deposition rate distribution.

### Example 6

In the magnetron sputtering apparatus including the magnet array body 5 of FIG. 2, the distance between the target 31 having a diameter of 400 mm and the wafer 10 having a diameter of 300 mm was set to 20 mm, and a deposition process was carried out under the processing conditions described above while rotating the magnet array body 5 in the apparatus shown in FIG. 2 to obtain the deposition rate distribution in the radial direction of the wafer. An input power density is a value obtained by dividing an input power by the area of the target, and the process was carried out under conditions that the input power density was 4.5 W/cm², 3.2 W/cm², and 1.6 W/cm².

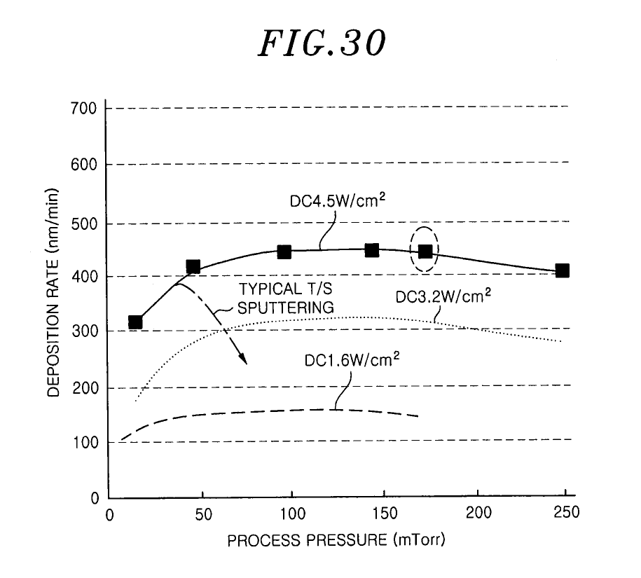

The results are shown in FIG. 30, wherein the horizontal axis represents the pressure in the vacuum chamber 2, and the vertical axis represents the deposition rate. The case of the input power density of 4.5 W/cm² is indicated by a solid line, the case of the input power density of 3.2 W/cm² is indicated by a dotted line, the case of the input power density of 1.6 W/cm² is indicated by a dashed line, and the case of the sputtering apparatus shown in FIG. 33 is indicated by a dashed dotted line. The deposition rate is better as the power applied to the target is larger. In the case of the input power density of 4.5 W/cm², the deposition rate increases with the pressure up to about 13.3 Pa (100 mTorr), and is almost constant after it reaches 450 mm/min. Further, in the case of the input power density of 3.2 W/cm², the deposition rate increases with the pressure up to about 13.3 Pa (100 mTorr), and is almost constant after it reaches 300 mm/min. On the other hand, in the sputtering (target-substrate distance=50 mm) in the conventional apparatus shown in FIG. 33, the deposition rate decreases after the pressure exceeds a certain value. Discussion of the difference between these results will be considered in conjunction with Example 7.

### Example 7

By the magnetron sputtering apparatus used in the Example 6, a relationship between the current density flowing through the target and the target voltage (the DC voltage applied to the target) for each pressure was obtained by variously changing the process pressure. As the process pressure, five values of 0.91, 3.59, 13.0, 19.6, 23.3 Pa (7, 27, 98, 147, 175 mTorr) were set.

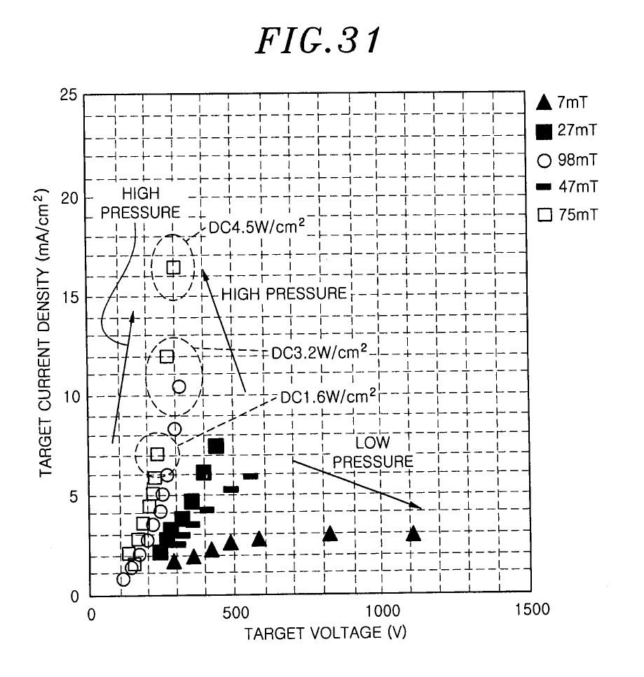

These results are shown in FIG. 31, wherein the horizontal axis represents the target voltage, and the vertical axis represents the current density flowing through the target (see legend). Although the same power is supplied to the target 31, the current density is high and the voltage is low under high pressure conditions. From the plot, it can be confirmed that for the same target voltage, the current density is high at a high pressure, whereas the current density is low at a low pressure. Further, when increasing the target power under high pressure, unlike the case of low pressure, the target current density can be increased almost without increasing the target voltage. A high current state corresponds to increasing the number of Ar ions in the plasma. If the pressure is high, the collision frequency between electrons and argon atoms increases and the ionization is carried out vigorously. Accordingly, the number of Ar ions increases and the current flowing through the target increases. If the pressure is high, collisions between sputtered atoms and argon ions and between sputtered atoms are violent, diffusion takes place, and the sputtered atoms diffuse not only in the direction perpendicular to the target surface, but also toward the surrounding wall in the direction parallel to the target surface, thereby reducing the deposition rate. It is apparent that this phenomenon becomes more prominent as the distance between the target and the substrate is larger. In the conventional sputtering technique, the deposition rate decreases at a pressure of 6.65 Pa (50 mTorr) or more, whereas in the narrow gap of the present embodiment, the deposition rate is not decreased even at higher pressures. Further, since a sufficient deposition rate was obtained at the input power density of 3.2 W/cm² in Example 6, it can be inferred that the object of the present invention can be achieved sufficiently at the power density of 3.2 W/cm² or more. The deposition rate is high and is not decreased even under high pressure conditions because of the narrow gap and the discharge being performed on the entire surface of the target by the magnets of the present invention.

### Example 8

By the magnetron sputtering apparatus used in the Example 6, the target input power density was set to three values of 4.5 W/cm², 3.2 W/cm² and 1.6 W/cm², and a relationship between the resistivity of the W film formed on the wafer 10 and the process pressure was examined for each setting condition.

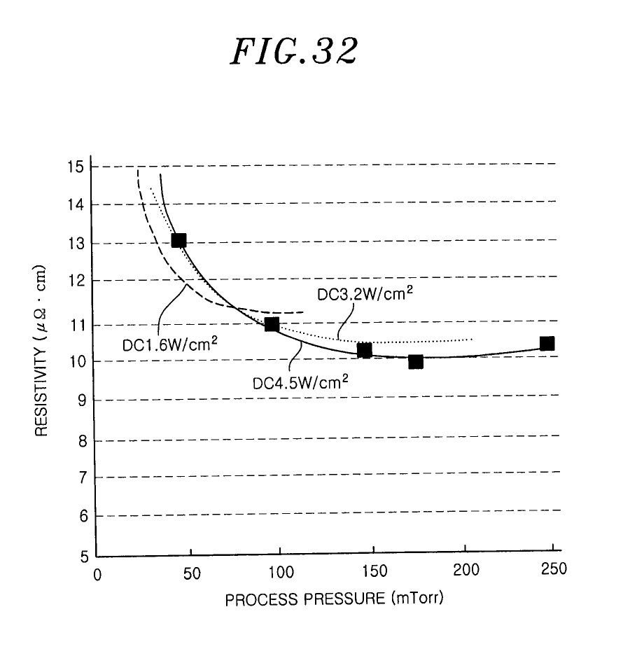

The results are shown in FIG. 32, wherein the horizontal axis represents the process pressure, and the vertical axis represents the resistivity of the W film. The case of the input power density of 4.5 W/cm² is indicated by a solid line, the case of the input power density of 3.2 W/cm² is indicated by a dotted line, and the case of the input power density of 1.6 W/cm² is indicated by a dashed line. From the graph, in the cases where the input power density is 4.5 W/cm² and 3.2 W/cm², the resistivity of the W film is reduced to about 10 μΩ·cm with the pressure, whereas in the case where the input power density is 1.6 W/cm², the resistivity of the W film is reduced to about 11 μΩ·cm.

It is considered that one of the reasons that the resistivity decreases with the pressure is that if the pressure increases, the number of Ar ions also increases, and the number of Ar ions incident on the wafer 10 increases, so that energy is applied to the surface of the W film to promote surface diffusion of W particles. As another reason, it can be inferred that the rebounding Ar atoms described above lose energy with the pressure increase, and no longer reach the wafer 10.

When considered in conjunction with the graph of FIG. 32, the upper limit of the pressure in the vacuum chamber 2 is may be any pressure at which the W film can be deposited at a low resistance in the vicinity of, e.g., 10 μΩ·cm, and is about 200 mTorr in this case. The same is true for the upper limit of the input power density. When the film can be formed in the vicinity of, e.g., 10 μΩ·cm, the upper limit of the input power density can be estimated to be, e.g., 10 W/cm².

Here, an inference about the surface diffusion of the W particles will be made.

In a document (J. J. Cuomo; Handbook of Ion Beam Technol. (1989) p. 194), there have been proposed the conditions for allowing the incident particles to cause the surface diffusion on the film surface in sputtering. According to this, the interpretation that the W particles can move when the sum of the energy incident on the film surface is greater than the sum of the binding energy of W has been made. That is, it can be represented as follows:

Sum of binding energy of W<(J₊/Jₘ)×V_{dc} . . . (5), where J₊, Jₘ and V_{dc} respectively represent the number of ions in a case where all incident particles are ions, the number of W atoms in the same case, and a DC voltage applied from the high frequency power supply unit 41 to the sheath which is formed directly on the substrate. As described above, if the high frequency power applied to the substrate is increased, since damage is given to the deposited W film, it is preferable to increase J₊ rather than increasing V_{dc}. A sputtering threshold of the W film is 33 eV, and metal binding energy of W is 9 eV. Thus, from Expression (5), the following is established.

(J₊/Jₘ)×33 eV>9 eV (6)

If the deposition rate of the W film is assumed to be 300 nm/min, since Jₘ is 3×10¹⁶/cm² sec, the incident amount of ions J₊ is at least 8×10¹⁵/cm² sec. If J₊ is determined, the spatial ion density is also determined. Since the order of the density is 10⁴ lower than J₊, the order of the spatial ion density is at least 10¹¹/cm³. Further, if the pressure increases, the ion density increases and the deposition rate also increases. Further, since a low pressure atmosphere is formed under the conditions of the typical sputtering apparatus in which the target-substrate distance is larger than 30 mm, the order of the spatial ion density is 10⁹/cm³. Therefore, in the typical sputtering apparatus, it is necessary to increase V_{dc} at which the ion density is small, but as described above, the Ar ions having excessive energy are attracted to the W film, and defects occur in the deposited W film. Since the sputtering threshold of W is 33 eV, the energy of the ions should be on the order of about several tens of eV.

Here, in the case where the DC power input density per unit area of the target is 4.5 W/cm², when the DC voltage is 300 V, the current density in the electron drifting portion is calculated to be 15 mA/cm². Since the area of the target is smaller than the electron drifting portion, the current density in the vicinity of the target is greater than this value, and the ion density in the vicinity of the target is equal to or greater than about 1×10¹²/cm³. According to a document (M. A. Liberman; Principles of Plasma Discharges and Materials Processing (1994) pp. 469-470), J₊ in this case can be calculated by the following expression:

J₊=0.61e·nᵢ·uB (7)

where e is the charge of one electron, nₗ is the ion density, and uB is Bohm speed.

In this embodiment, since the distance between the target and the substrate is as short as 20 mm, there is no large difference between the ion density in the vicinity of the target and the ion density in the vicinity of the substrate, and the ion density can be estimated on the order of about 10¹¹/cm³. Therefore, it can be inferred that the ion density is about two orders higher than that in the sputtering of the conventional technique.

As described above, in order to reduce the resistivity of the W film, it is important to increase the ion density and reduce V_{dc}. However, in the conventional magnetron sputtering apparatus, it is difficult to obtain such conditions while maintaining a high deposition rate. Thus, the resistivity of the W film becomes high.

To be specific, in the conventional magnetron sputtering apparatus, since the distance between the target and the substrate is long, the ion density on the substrate is as low as 10⁹/cm³, the discharge is also non-uniform, and ions are generated only intermittently. Accordingly, there are places where plasma conversion can be performed only locally. In places where plasma conversion is not performed on the substrate, although sputtered W particles fly to the places, the W particles are not favorably deposited on the substrate surface since ions are not present in the places. On the other hand, in places where plasma conversion is performed, since ions are present in the places, the W particles are favorably deposited on the substrate surface. Therefore, parts where the W particles are in a good state and parts where the W particles are in a bad state are stacked, and a film in poor condition is formed as a whole. As a result, the resistivity of the formed W film becomes high.

On the other hand, in the present invention, the distance between the target and the substrate is a narrow gap of 20 mm, and entire discharge occurs while satisfying at all times the above-mentioned Expression (5):

Sum of binding energy of W<(J₊/Jₘ)×V_{dc}. Accordingly, since ions are successively irradiated at a high density even in the rotation of magnets, the W particles can be deposited favorably on the entire substrate and, thus, a film with low resistivity is formed. Further, the deposition rate is also maintained at a high speed of 400 nm/min or more. The same is true for the deposition of Ta, Ti, Mo, Ru, Hf, Co, and Ni other than W.

According to the present invention, the N pole magnets and S pole magnets are arranged to be spaced from each other along the surface facing the target to constitute the magnet group, and the magnets located on the outermost periphery of the magnet group are arranged in a line. Thus, since a plasma is generated based on the drift of electrons by the cusp magnetic field and the electrons are prevented from jumping out, a high density plasma is formed uniformly. Further, since the N pole magnets and S pole magnets are arranged to be spaced from each other along the surface facing the target, the in-plane uniformity of the erosion formed on the target based on the horizontal magnetic field of these magnets is improved. Therefore, since sputtering can be performed while the target and the substrate are brought close to each other, it is possible to improve the deposition efficiency while ensuring the in-plane uniformity of the deposition rate. Further, since the erosion proceeds with uniformity in the surface of the target due to the high uniformity of plasma density, the utilization efficiency of the target is improved and the life of the target is longer as compared with the case where the erosion locally proceeds. According to another aspect of the present invention, by a method for performing sputtering in a state of high power density under high process pressure of 100 mTorr or more by using the apparatus of the present invention, since the ion density in the generated plasma is high to become a stable state, the plasma density becomes uniform on the substrate. Therefore, since fast and uniform sputtering can be performed on the substrate, it is possible to form a low resistance film on the substrate while maintaining a fast deposition rate.

While the invention has been shown and described with respect to the embodiments, it will be understood by those skilled in the art that various changes and modification may be made without departing from the scope of the invention as defined in the following claims.

What is claimed is:

1. A magnetron sputtering apparatus in which a target is disposed to face a substrate to be processed, which is placed in a vacuum chamber, and magnets are provided on a rear side of the target, the apparatus comprising:
a power supply unit for applying a voltage to the target;
a magnet array body including a magnet group arranged on a base body; and
a rotating mechanism for rotating the magnet array body around an axis perpendicular to the substrate,
wherein in the magnet array body, N poles and S poles constituting the magnet group are arranged to be spaced from each other along a surface facing the target such that a plasma is generated based on a drift of electrons by a cusp magnetic field,
magnets located on the outermost periphery of the magnet group are arranged in a line to prevent the electrons from being released from constraint of the cusp magnetic field and jumping out of the cusp magnetic field, and
a distance between the target and the substrate during sputtering is equal to or less than 30 mm.

2. A magnetron sputtering apparatus in which a target is disposed to face a substrate to be processed, which is placed in a vacuum chamber, magnets are provided on a rear side of the target, and a magnetron sputtering process is performed on the substrate which is a semiconductor wafer having a diameter of 300 mm, the apparatus comprising:
a power supply unit for applying a voltage to the target;
a magnet array body including a magnet group arranged on a base body; and
a rotating mechanism for rotating the magnet array body around an axis perpendicular to the substrate,
wherein in the magnet array body, N poles and S poles constituting the magnet group are arranged to be spaced from each other along a surface facing the target such that a plasma is generated based on a drift of electrons by a cusp magnetic field,
magnets located on the outermost periphery of the magnet group are arranged in a line to prevent the electrons from being released from constraint of the cusp magnetic field and jumping out of the cusp magnetic field, and
if R (mm) is a diameter of the target and TS (mm) is a distance between the target and the substrate, the distance TS is set to satisfy
(TS′/R)×100(%)=0.0006151R²−0.5235R+113.4, and
TS≦1.1TS′.

3. A magnetron sputtering apparatus in which a target is disposed to face a substrate to be processed, which is placed in a vacuum chamber, magnets are provided on a rear side of the target, and a magnetron sputtering process is performed on the substrate which is a semiconductor wafer having a diameter of 450 mm, the apparatus comprising:
a magnet array body including a magnet group arranged on a base body; and
a rotating mechanism for rotating the magnet array body around an axis perpendicular to the substrate,
wherein in the magnet array body, N poles and S poles constituting the magnet group are arranged to be spaced from each other along a surface facing the target such that a plasma is generated based on a drift of electrons by a cusp magnetic field,
magnets located on the outermost periphery of the magnet group are arranged in a line to prevent the electrons from being released from constraint of the cusp magnetic field and jumping out of the cusp magnetic field, and
if R (mm) is a diameter of the target and TS (mm) is a distance between the target and the substrate, the distance TS is set to satisfy
(TS′/R)×100(%)=0.0003827R²−0.4597R+139.5, and
TS≦1.1TS′.

4. The magnetron sputtering apparatus of claim 1, wherein in the magnet array body, the N poles and S poles constituting the magnet group are arranged such the plasma is generated over an entire projection area of the substrate.

5. The magnetron sputtering apparatus of claim 2, wherein in the magnet array body, the N poles and S poles constituting the magnet group are arranged such the plasma is generated over an entire projection area of the substrate.

6. The magnetron sputtering apparatus of claim 3, wherein in the magnet array body, the N poles and S poles constituting the magnet group are arranged such the plasma is generated over an entire projection area of the substrate.

7. The magnetron sputtering apparatus of claim 1, wherein the magnet array body includes a group of main magnets and a group of auxiliary magnets, N poles and S poles of the main magnet group are disposed in a direction perpendicular to a surface of the target, N poles and S poles of the auxiliary magnet group are disposed in a direction parallel to the surface of the target, and magnetic poles of the main magnets adjacent to one sides of the auxiliary magnets are set to have the same polarity as magnetic poles of the one sides of the auxiliary magnets on a side of the target.

8. The magnetron sputtering apparatus of claim 2, wherein in the magnet array body, the N poles and S poles constituting the magnet group are arranged such the plasma is generated over an entire projection area of the substrate.

9. The magnetron sputtering apparatus of claim 3, wherein in the magnet array body, the N poles and S poles constituting the magnet group are arranged such the plasma is generated over an entire projection area of the substrate.

10. The magnetron sputtering apparatus of claim 1, further comprising:
an electrode which is provided on a side of the substrate opposite to the target; and
a high frequency power supply unit for supplying a high frequency power to the electrode.

11. The magnetron sputtering apparatus of claim 2, further comprising:
an electrode which is provided on a side of the substrate opposite to the target; and
a high frequency power supply unit for supplying a high frequency power to the electrode.

12. The magnetron sputtering apparatus of claim 3, further comprising:
an electrode which is provided on a side of the substrate opposite to the target; and
a high frequency power supply unit for supplying a high frequency power to the electrode.

13. The magnetron sputtering apparatus of claim 1, wherein when the magnets located on the outermost periphery are referred to as return magnets, a magnetic force of at least one of outside magnets located on the outermost periphery in the magnet group except the return magnets is smaller than a magnetic force of a magnet located inwardly of the outside magnets.

14. The magnetron sputtering apparatus of claim 2, wherein when the magnets located on the outermost periphery are referred to as return magnets, a magnetic force of at least one of outside magnets located on the outermost periphery in the magnet group except the return magnets is smaller than a magnetic force of a magnet located inwardly of the outside magnets.

15. The magnetron sputtering apparatus of claim 3, wherein when the magnets located on the outermost periphery are referred to as return magnets, a magnetic force of at least one of outside magnets located on the outermost periphery in the magnet group except the return magnets is smaller than a magnetic force of a magnet located inwardly of the outside magnets.

16. The magnetron sputtering apparatus of claim 13, wherein magnets located inwardly of the return magnets are configured to be divided into magnet elements, and a magnetic force of the magnets can be adjusted by the number of the magnet elements thereof.

17. The magnetron sputtering apparatus of claim 16, wherein in the magnets located inwardly of the return magnets, a sum of strengths of magnets corresponding to the N poles is equal to a sum of strengths of magnets corresponding to the S poles.

18. The magnetron sputtering apparatus of claim 16, wherein the magnets located inwardly of the return magnets are arranged in a matrix.

19. A magnetron sputtering method using the magnetron sputtering apparatus described in claim 1, the method comprising:
depositing a metal film on the substrate under the condition that a process pressure is set to be equal to or greater than 13.3 Pa (100 mTorr), and an input power density obtained by dividing an input power to the target by an area of the target is set to be equal to or greater than 3 W/cm².
